(19) United States
(12) Patent Application Publication
(10) Pub. No.: US 2023/0197793 A1
(43) Pub. Date: Jun. 22, 2023

(54) FIELD-EFFECT TRANSISTOR DEVICE

(71) Applicants: Shinichiro TAKATANI, Tokyo (JP); Riichiro SHIROTA, Kanagawa (JP)

(72) Inventors: Shinichiro TAKATANI, Tokyo (JP); Riichiro SHIROTA, Kanagawa (JP)

(21) Appl. No.: 17/953,499

(22) Filed: Sep. 27, 2022

(30) Foreign Application Priority Data
Dec. 22, 2021 (JP) JP2021-208736

(51) Int. Cl. H01L 29/20; H01L 29/778; H01L 29/423; H01L 29/40; H01L 29/06

(52) U.S. Cl. CPC H01L 29/2003; H01L 29/7787; H01L 29/42324; H01L 29/402; H01L 29/0692

(57) ABSTRACT

A normally-off field effect transistor device includes a gate electrode structure having a first insulating film, a charge-accumulation gate electrode, a second insulating film and a gate electrode deposited one by one on a semiconductor, and a first capacitor formed by capacitive coupling between the charge-accumulation gate electrode and a source electrode. A charge is accumulated on the charge-accumulation gate electrode by a first current flowing through the first capacitor. The gate electrode structure further includes a stacked film having a third insulating film and a first semiconductor layer provided between the source electrode and the charge-accumulation gate electrode, with at least part of the first current flowing through the stacked film.

### CROSS REFERENCE TO RELATED APPLICATION

The application claims the benefit of Japan application serial No. 2021-208736, filed on Dec. 22, 2021, and the entire contents of which are incorporated herein by reference.

### BACKGROUND OF THE INVENTION

### 1. Field of the Invention

The present invention relates to a semiconductor transistor device, and in particular to a field-effect transistor device that realizes a so-called normally-off device in which the conduction channel under the gate electrode is substantially in an off-state when no voltage is applied to the gate electrode.

### 2. Description of the Related Art

Semiconductors with a wide bandgap are useful for electronic devices that operate at high voltages. Among them, nitride semiconductors composed of nitrides such as GaN, AlN, InN and ScN, or mixed crystals of these, are suitable for high-voltage, high-power electronic devices because of their high mobility of conduction electrons as well as their wide bandgap. Field-effect transistors (FETs) made from nitride semiconductors and one form of such transistors, high electron mobility transistors (HEMTs), that use conduction electrons induced at the heterojunction interface of semiconductors such as AlGaN/GaN as the conduction channel, in particular, can operate at high voltages and high currents with low on-resistance, being used as transistors for power switches and high-frequency power amplifiers.

However, nitride semiconductor FETs are usually so-called normally-on types in which the conduction channel under the gate electrode is in an on-state when no voltage is applied to the gate electrode. In other words, the gate voltage at which the current flowing between the source and drain electrodes is interrupted, the so-called threshold voltage, is negative. For example, when nitride semiconductor FETs are used as power switches for power supplies or the like, the switch opens when the control voltage applied to the gate electrode is lost due to malfunction or the like. This may lead to damage to the entire device, which is undesirable from a safety point of view, etc.

For this reason, technologies have been developed to make nitride semiconductor FETs normally-off i.e., to set the threshold voltage to a positive value. One known method is to provide a floating gate electrode for charge accumulation between the gate electrode and the conduction channel (see Japanese Patent Publication No. 2020-092193). FIG. 10 shows the structure of a nitride semiconductor HEMT according to the prior art. A buffer layer 1002, a GaN layer 1003 and an AlGaN layer 1004 are deposited one by one on a substrate 1001, and a conduction channel 1010 is formed on the side of the GaN layer 1003 at the interface between the GaN layer 1003 and the AlGaN layer 1004. A charge-accumulation gate electrode 1006 is formed on a first insulating film 1005 above the AlGaN layer 1004, and a gate electrode 1012 is formed on a second insulating film 1011 above top of it. A source electrode 1008 and a drain electrode 1009 are formed horizontally with the charge-accumulation gate electrode 1006 in between. Both the source electrode 1008 and the drain electrode 1009 are electrically connected to the conduction channel 1010 within the area surrounded by a device separation region 1014. The capacitor formed between the gate electrode 1012 and the charge-accumulation gate electrode 1006 with the second insulating film 1011 as the capacitance film is called a second capacitor. The capacitor formed between the charge-accumulation gate electrode 1006 and the conduction carrier 1013 of the gate electrode portion in the conduction channel 1010 below the gate electrode, with the first insulating film 1005 as the capacitance film, is called a third capacitor. The voltage applied to the gate electrode 1012 is capacitively coupled to the conduction carrier 1013 of the gate electrode portion via the second and third capacitors connected in series, thereby changing the number of carriers. This allows the current flowing between the source electrode 1008 and the drain electrode 1009 to be regulated, thus providing operation as an FET. In this prior art, a charge-injection electrode 1007 is further provided, and the first capacitor is formed with the charge-accumulation gate electrode 1006 via a third insulating film 1015. FIG. 11A shows a schematic view of a part of the nitride semiconductor HEMT shown in FIG. 10. FIGS. 11B through 11F show the energy of the lower end of the conduction band (Ec) and the upper end of the valence band (Ev) along the cross-sections connecting the symbols shown in FIG. 11A, that is, the interior of the gate electrode 1012 A, the interior of the charge-accumulation gate electrode 1006 B, the interior of the GaN layer 1003 C and the interior of the charge-injection electrode 1007 D. A (1012), B (1006) and D (1007) are the Fermi levels of metal at each position. FIG. 11B shows the view without externally applied voltage. The AlGaN layer 1004 has a slope of energy of the lower end of the conduction band and the upper end of the valence band due to polarization, resulting in the energy at the lower end of the conduction band of the GaN layer 1003 being lower than the Fermi level 1104 at the interface with the AlGaN layer 1004, generating the conduction carrier 1013 of the gate electrode portion. This means that the FET is normally-on. Here, the respective electrode areas as well as the dielectric constants and thicknesses of the second and third insulating films 1011 and 1015 are selected so that a capacitance of the first capacitor is sufficiently smaller than a capacitance of the second capacitor. In this case, when a positive voltage 1101 indicated by the arrow in FIG. 11C is applied to the gate electrode 1012 with reference to the charge-injection electrode 1007, the strong capacitive coupling of the second capacitor with the gate electrode 1012 raises the potential of the charge-accumulation gate electrode 1006, lowering the potential energy of conduction electrons in the charge-accumulation gate electrode 1006. Then the potential difference between the charge-accumulation gate electrode 1006 and the charge-injection electrode 1007 increases, and a high electric field is applied to the third insulating film 1015, causing a tunnel current 1102 of conduction electrons, indicated by the arrow in FIG. 11C, to flow through the first capacitor. As a result, a negative charge 1103 is accumulated on the charge-accumulation gate electrode 1006. Depending on the material of the third insulating film 1015, conduction holes may tunnel through the third insulating film 1015 from the charge-accumulation gate electrode 1006 to become a current flowing through the first capacitor. In this case, a negative charge is accumulated on the charge-accumulation gate electrode 1006 in the same way. Hereafter in this patent description, only the case where conduction electrons tunnel will be explained. FIG. 11D shows the energy of the lower end of the conduction band and the upper end of the valence band when the positive voltage 1101 is discontinued after the negative charge 1103 is accumulated. The potential energy of conduction electrons in the charge-accumulation gate electrode 1006 increases due to the negative charge 1103, which raises the energy of the lower end of the conduction band and the upper end of the valence band of the AlGaN layer 1004 and the GaN layer 1003, resulting in the energy of the lower end of the conduction band of the GaN layer 1003 being higher than the Fermi level 1104 and the conduction carrier 1013 of the gate electrode portion disappearing. This means that the nitride semiconductor HEMT is made normally-off.

### SUMMARY OF THE INVENTION

The first problem that the invention aims to solve is described below. In the nitride semiconductor FET shown in FIG. 10, it is assumed that the charge-injection electrode 1007 is connected to an external terminal in the same way as other electrodes and is always connected to an external circuit. It is difficult to completely isolate the potential of the external terminal connected to the charge-injection electrode 1007, usually leaving a leakage path to the ground potential. FIG. 11E shows the case where the potentials of the charge-injection electrode 1007 and the gate electrode 1012 are both zero. A negative charge 1103, which is accumulated in the charge-accumulation gate electrode 1006 to make the FET normally-off, creates a potential difference between the charge-accumulation gate electrode 1006 and the charge-injection electrode 1007, resulting in a slope of the energy of the lower end of the conduction band and the upper end of the valence band in the third insulating film 1015, and an electric field in the opposite direction from that during the charge injection in the third insulating film 1015. In other words, a potential difference of opposite polarity from that during negative charge accumulation is generated between the electrodes of the first capacitor. In addition, when the FET is used as a power switch, for example, dynamic voltage fluctuations occur due to various reactance components of the FET and switch-drive circuit during on-off operation, which may lead to the negative voltage 1104 indicated by the arrow in FIG. 11F being applied to the gate electrode 1012 with reference to the charge-injection electrode 1007. In this case, the strong capacitive coupling in the second capacitor further lowers the potential of the charge-accumulation gate electrode 1006, leading to a larger potential difference between the charge-accumulation gate electrode 1006 and the charge-injection electrode 1007. As a result, the strong electric field in the third insulating film 1015 generates a tunnel current 1105, and the accumulated negative charge 1103 flows back to the charge-injection electrode 1007. This causes the threshold voltage to return to the negative direction, thereby shortening the time to hold the positive threshold voltage required for normally-off operation. The first objective of the present invention is to provide a new field-effect transistor device that solves the above first problem.

Next, the second problem that the invention aims to solve will be described below. FETs are generally three-terminal devices and operate with three electrodes of a source electrode, a drain electrode and a gate electrode, but in the above prior art, a charge-injection electrode 1007 is added, making the total number of electrodes four. Therefore, four terminals are required to supply voltages from external terminals, which complicates the external circuit to operate the FET. It also complicates the FET manufacturing process and further increases the area occupied by the FET on a substrate. The second objective of the present invention is to provide a new field-effect transistor device that solves the above second problem.

Next, the third problem that the invention aims to solve will be described below. In the prior art shown in FIG. 10, when local defects exist in the first insulating film 1005, the second insulating film 1011 or the third insulating film 1015 contacting the charge-accumulation gate electrode 1006, the negative charge accumulated on the charge-accumulation gate electrode 1006 may leak out through the defects. In addition, when a local electric field concentration occurs in a part of the charge-accumulation gate electrode 1006, the negative charge accumulated on the charge-accumulation gate electrode 1006 may leak out due to tunneling in that part. This shortens its lifetime as a normally-off FET. A leakage of accumulated charge during operation that instantly changes it to normally-on may cause damage to the device. The third objective of the present invention is to provide a new field-effect transistor device that solves the above third problem.

The field-effect transistor device according to the first invention of the present application to achieve the first objective of the invention includes a semiconductor, a conduction channel provided in or on a surface of the semiconductor, a first insulating film provided in proximity to the conduction channel, a charge-accumulation gate electrode provided at least in part above a side of the first insulating film opposite to the conduction channel, a second insulating film provided above a side of the charge-accumulation gate electrode opposite to the first insulating film, a gate electrode provided at least in part above a side of the second insulating film opposite to the charge-accumulation gate electrode, a source electrode and a drain electrode provided on the semiconductor with the charge-accumulation gate electrode in between and electrically connected to the conduction channel, a charge-injection electrode forming a first capacitor by capacitive coupling with the charge-accumulation gate electrode, and a stacked film including a third insulating film and a first semiconductor layer provided between the charge-injection electrode and the charge-accumulation gate electrode, where a charge is accumulated on the charge-accumulation gate electrode by a first current flowing through the first capacitor, and at least part of the first current flows through the stacked film.

In a preferred form of the first invention of the present application, the third insulating film faces the charge-accumulation gate electrode and the first semiconductor layer faces the charge-injection electrode, and the first semiconductor layer includes n-type impurities.

In a preferred form of the first invention of the present application, the third insulating film faces the charge-injection electrode and the first semiconductor layer faces the charge-accumulation gate electrode, and the first semiconductor layer includes p-type impurities.

The field-effect transistor device according to the second invention of the present application to achieve the second objective of the invention includes a semiconductor, a conduction channel provided in or on a surface of the semiconductor, a first insulating film provided in proximity to the conduction channel, a charge-accumulation gate electrode provided at least in part above a side of the first insulating film opposite to the conduction channel, a second insulating film provided above a side of the charge-accumulation gate electrode opposite to the first insulating film, a gate electrode provided at least in part above a side of the second insulating film opposite to the charge-accumulation gate electrode, and a source electrode and a drain electrode provided on the semiconductor with the charge-accumulation gate electrode in between and electrically connected to the conduction channel, where the source electrode or the drain electrode forms a first capacitor by capacitive coupling with the charge-accumulation gate electrode, and a charge is accumulated on the charge-accumulation gate electrode by a first current flowing through the first capacitor.

In a preferred form of the second invention of the present application, the field-effect transistor device further includes a stacked film including a third insulating film and a first semiconductor layer provided between the source electrode or the drain electrode and the charge-accumulation gate electrode forming the first capacitor, and at least part of the first current flows through the stacked film.

In a preferred form of the second invention of the present application, the third insulating film faces the charge-accumulation gate electrode and the first semiconductor layer faces the source electrode or the drain electrode forming the first capacitor, and the first semiconductor layer includes n-type impurities.

In a preferred form of the second invention of the present application, the third insulating film faces the source electrode or the drain electrode forming the first capacitor and the first semiconductor layer faces the charge-accumulation gate electrode, and the first semiconductor layer includes p-type impurities.

The field-effect transistor device according to the third invention of the present application to achieve the third objective of the invention includes a semiconductor, a conduction channel provided in or on a surface of the semiconductor, a first insulating film provided in proximity to the conduction channel, a charge-accumulation gate electrode provided at least in part above a side of the first insulating film opposite to the conduction channel, a second insulating film provided above a side of the charge-accumulation gate electrode opposite to the first insulating film, a gate electrode provided at least in part above a side of the second insulating film opposite to the charge-accumulation gate electrode, and a source electrode and a drain electrode provided on the semiconductor with the charge-accumulation gate electrode in between and electrically connected to the conduction channel, where the charge-accumulation gate electrode includes multiple separated electrodes.

In a preferred form of the third invention of the present application, all of the multiple electrodes of the charge-accumulation gate electrode are arranged to intersect a direction of the current in the conduction channel.

In a preferred form of the third invention of the present application, all of the multiple electrodes of the charge-accumulation gate electrode are arranged along a direction of the current in the conduction channel.

In a preferred form of the third invention of the present application, the field-effect transistor device further includes a charge-injection electrode forming a first capacitor by capacitive coupling with the charge-accumulation gate electrode, and a charge is accumulated on the charge-accumulation gate electrode by a first current flowing through the first capacitor.

In a preferred form of the third invention of the present application, the field-effect transistor device further includes a charge-injection electrode that forms a first capacitor by capacitive coupling with the charge-accumulation gate electrode, where a charge is accumulated on the charge-accumulation gate electrode by a first current flowing through the first capacitor, and further includes a stacked film including a third insulating film and a first semiconductor layer provided between the charge-injection electrode and the charge-accumulation gate electrode, where at least part of the first current flows through the stacked film.

In a preferred form of the third invention of the present application, the field-effect transistor device further includes a charge-injection electrode that forms a first capacitor by capacitive coupling with the charge-accumulation gate electrode, where a charge is accumulated on the charge-accumulation gate electrode by a first current flowing through the first capacitor, and further includes a stacked film including a third insulating film and a first semiconductor layer provided between the charge-injection electrode and the charge-accumulation gate electrode, where at least part of the first current flows through the stacked film, the third insulating film faces the charge-accumulation gate electrode, the first semiconductor layer faces the charge-injection electrode, and the first semiconductor layer includes n-type impurities.

In a preferred form of the third invention of the present application, the field-effect transistor device further includes a charge-injection electrode forming a first capacitor by capacitive coupling with the charge-accumulation gate electrode, where a charge is accumulated on the charge-accumulation gate electrode by a first current flowing through the first capacitor, and further includes a stacked film including a third insulating film and a first semiconductor layer provided between the charge-injection electrode and the charge-accumulation gate electrode, where at least part of the first current flows through the stacked film, the third insulating film faces the charge-injection electrode, the first semiconductor layer faces the charge-accumulation gate electrode, and the first semiconductor layer includes p-type impurities.

In a preferred form of the third invention of the present application, the source electrode or the drain electrode forms a first capacitor by capacitive coupling with the charge-accumulation gate electrode, and a charge is accumulated on the charge-accumulation gate electrode by a first current flowing through the first capacitor.

In a preferred form of the third invention of the present application, the source electrode or the drain electrode forms a first capacitor by capacitive coupling with the charge-accumulation gate electrode, where a charge is accumulated on the charge-accumulation gate electrode by a first current flowing through the first capacitor, and a stacked film including a third insulating film and a first semiconductor layer is provided between the source electrode or the drain electrode and the charge-accumulation gate electrode forming the first capacitor, where at least part of the first current flows through the stacked film.

In a preferred form of the third invention of the present application, the source electrode or the drain electrode forms a first capacitor by capacitive coupling with the charge-accumulation gate electrode, where a charge is accumulated on the charge-accumulation gate electrode by a first current flowing through the first capacitor, and a stacked film including a third insulating film and a first semiconductor layer is provided between the source electrode or the drain electrode and the charge-accumulation gate electrode forming the first capacitor, where at least part of the first current flows through the stacked film, the third insulating film faces the charge-accumulation gate electrode, the first semiconductor layer faces the source electrode or the drain electrode forming the first capacitor, and the first semiconductor layer includes n-type impurities.

In a preferred form of the third invention of the present application, the source electrode or the drain electrode forms a first capacitor by capacitive coupling with the charge-accumulation gate electrode, where a charge is accumulated on the charge-accumulation gate electrode by a first current flowing through the first capacitor, and a stacked film including a third insulating film and a first semiconductor layer is provided between the source electrode or the drain electrode and the charge-accumulation gate electrode forming a first capacitor, where at least part of the first current flows through the stacked film, the third insulating film faces the source electrode or the drain electrode forming the first capacitor, the first semiconductor layer faces the charge-accumulation gate, and the first semiconductor layer includes p-type impurities.

According to the first invention of the present application, the magnitude of the current flowing through the first capacitor can be made asymmetric between the case where the potential of the charge-accumulation gate electrode is lower than that of the charge-injection electrode and the case where the potential of the charge-accumulation gate electrode is higher. For example, while a negative charge can be accumulated on the charge-accumulation gate electrode by making the potential of the charge-accumulation gate electrode higher than that of the charge-injection electrode, the outflow of the negative charge can be suppressed when the opposite potential difference is generated. When the FET is used as a power switch and a negative charge is accumulated on the charge-accumulation gate electrode to make it normally-off, various reactance components in the FET and switch drive circuit may cause dynamic voltage fluctuations, resulting in a negative dynamic voltage at the gate electrode, and the potential of the charge-accumulation gate electrode being lower than that of the charge-injection electrode due to the capacitive coupling with the gate electrode, but the outflow of the negative charge accumulated on the charge-accumulation gate electrode to the charge-injection electrode in that case can be suppressed. As a result, the positive threshold voltage required for the normally-off operation can be maintained for a long duration.

The effects of the first invention of the present application will be explained in more detail using drawings. FIG. 12A shows a schematic view of a part of the FET according to the first invention of the present application. The difference from the prior FET shown in FIG. 11A is that a first semiconductor layer 1216 is provided between the third insulating film 1215 and the charge-injection electrode 1207. As in the description of the prior FET, the capacitor formed between the charge-injection electrode 1207 and the charge-accumulation gate electrode 1006 is called a first capacitor, between the gate electrode 1012 and the charge-accumulation gate electrode 1006 a second capacitor, and between the charge-accumulation gate electrode 1006 and the conduction carrier 1013 of the gate electrode portion a third capacitor. FIGS. 12B and 12C show the energy of the lower end of the conduction band (Ec) and the upper end of the valence band (Ev) of electrons along the cross-sections connecting the interior of the gate electrode 1012 A, the interior of the charge-accumulation gate electrode 1006 B and the interior of the charge-injection electrode 1207 D shown as the symbols in FIG. 12A. FIG. 12B shows the case where conduction electrons are injected from the charge-injection electrode 1207 into the charge-accumulation gate electrode 1006, where a positive voltage 1201 is applied to the gate electrode 1012 with reference to the charge-injection electrode 1207. This corresponds to FIG. 11C for the prior FET. Here, the respective electrode areas as well as the dielectric constants and thicknesses of the second and third insulating films 1011 and 1215 are selected so that a capacitance the first capacitor is sufficiently smaller than a capacitance of the second capacitor. Then the potential of the charge-accumulation gate electrode 1006 also significantly rises due to the strong capacitive coupling with the gate electrode 1012 by the second capacitor. At the same time, the first semiconductor layer 1216 is made n-type conductive so that the electrical contact with the charge-injection electrode 1207 is ohmic or near-ohmic with low resistance for conduction electrons. In this case, the energy at the lower end of the conduction band of the first semiconductor layer 1216 upon applying a positive voltage 1201 becomes almost flat, and the potential of conduction electrons at the interface with the third insulating film 1215 is almost the same as that of the charge-injection electrode 1207. As a result, the potential difference between the charge-accumulation gate electrode 1006 and the first semiconductor layer 1216 increases, and a high electric field is generated in the third insulating film 1215, causing a tunnel current 1202 of conduction electrons to flow as indicated by the arrow in FIG. 12B. The tunneling conduction electrons are accumulated as a negative charge 1203 on the charge-accumulation gate electrode 1006. In contrast, FIG. 12C shows the case where a negative voltage 1204, indicated by the arrow in the figure, is applied to the gate electrode 1012 with reference to the charge-injection electrode 1207. Such conditions are typically caused by dynamic fluctuations in voltage during on-off operation when an FET is used as a power switch. The strong capacitive coupling due to the second capacitor causes the potential of the charge-accumulation gate electrode 1006 to drop significantly. However, since the first semiconductor layer 1216 is n-type, carrier depletion occurs, and a part of the potential difference between the charge-accumulation gate electrode 1006 and the charge-injection electrode 1207 is compensated by the potential difference generated within the first semiconductor layer 1216. Therefore, the electric field in the third insulating film 1215 becomes smaller than in the case of the prior FET shown in FIG. 11F, suppressing the generation of a tunnel current. The outflow of the negative charge 1203 is suppressed, making it harder for the threshold voltage to return to the negative direction and thus allowing the positive threshold voltage required for normally-off operation to be easily maintained.

The effects of the first invention of the present application will be further explained in detail based on the result of a device simulation performed on the first capacitor. The simulation was performed for the parallel plate capacitor corresponding to the B-D cross-section in FIG. 12A. The third insulating film 1215 was silicon oxide (SiO2) with a thickness of 8 nm. The first semiconductor layer 1216 was silicon carbide (SiC) with a thickness of 40 nm with n-type conductivity and an impurity concentration of 1×10¹⁷ cm⁻³. FIG. 13 shows the simulation result of the current-voltage characteristic of the first capacitor. The voltage between the electrodes of the first capacitor shown on the horizontal axis corresponds to the voltage of the charge-accumulation gate electrode 1006 with reference to the charge-injection electrode 1207. The vertical axis shows the absolute value of the current on a logarithmic scale. The current-voltage characteristic is asymmetric between the negative and positive voltages, with the current being significantly lower in the negative voltage region than in the positive voltage region. For example, the current drop 1301 at −12V with reference to +12V indicated by the arrow in FIG. 13 is over nine orders of magnitude. As a result, even when a voltage in the opposite direction from that during negative charge accumulation is applied to the first capacitor due to dynamic fluctuations in voltage during on-off operation when using the FET as a switch, there is almost no outflow of accumulated charge.

In the method described above, the first semiconductor layer 1216 is provided on the side of the charge-injection electrode 1207, and the third insulating film 1215 is provided on the side of the charge-accumulation gate electrode 1006. Next, another method of the first invention of the present application will be explained using FIGS. 14A, 14B and 14C. FIG. 14A shows a schematic view of a part of the FET according to the first invention of the present application as in the case shown in FIG. 12A. In this method, the first semiconductor layer 1416 is provided on the side of the charge-accumulation gate electrode 1006, and the third insulating film 1415 is provided on the side of the charge-injection electrode 1407. The first semiconductor layer 1416 is p-type conductive so that the electrical contact with the charge-accumulation gate electrode 1006 is ohmic or near-ohmic with low resistance for conduction holes. FIG. 14B shows the case where a positive voltage 1401 is applied to the gate electrode 1012 with reference to the charge-injection electrode 1407. The energy of the lower end of the conduction band (Ec) and the upper end of the valence band (Ev) of the first semiconductor layer 1416, which is p-type, becomes almost flat, and the potential of conduction holes 1405 at the interface between the first semiconductor layer 1416 and the third insulating film 1415 is almost the same as that of the charge-accumulation gate electrode 1006. This increases the potential difference between the charge-injection electrode 1407 and the first semiconductor layer 1416, generating a strong electric field in the third insulating film 1415. As a result, a tunnel current 1402 of conduction electrons from the charge-injection electrode 1407 to the first semiconductor layer 1416 is generated, accumulating a negative charge 1403 on the charge-accumulation gate electrode 1006. In contrast, FIG. 14C shows the case where a negative voltage 1404 is applied to the gate electrode 1012 with reference to the charge-injection electrode 1407 due to dynamic fluctuations in voltage during switch operation. In this case, the voltage applied to the third insulating film 1415 decreases because a part of the potential difference between the charge-injection electrode 1407 and the charge-accumulation gate electrode 1006 is compensated by the first semiconductor layer 1416, which is p-type. This suppresses the generation of tunnel current and the reverse flow of the negative charge 1406 to the charge-injection electrode 1407.

The case where SiC is used for the first semiconductor layer is described above. SiC is known as a wide bandgap semiconductor. Impact ionization and Zener breakdown are less likely to occur in wide bandgap semiconductors with high breakdown field strength. This makes SiC suitable for the first invention of the present application, which suppresses tunneling in the insulating film by accepting part of the voltage upon applying the reverse voltage to the first capacitor from that during charge injection. In addition, in the example shown in FIG. 12A, the energy difference at the lower end of the conduction band between the third insulating film 1215 and the first semiconductor layer 1216, indicated by ΔEc in FIG. 12B, for a wide bandgap semiconductor is smaller, making the tunnel current 1202 flow more easily. In contrast, the leak current upon applying the reverse voltage is determined by the energy of the lower end of the conduction band of the third insulating film 1215 with reference to the Fermi level at the charge-accumulation gate electrode 1006, and thus is almost independent of the bandgap of the first semiconductor layer 1216 as shown in FIG. 12C. This makes a wide bandgap semiconductor suitable for the first semiconductor layer 1216 of the first invention of the present application because the difference in current between the case where a voltage to inject a negative charge is applied and the case where the reverse voltage is applied, can be increased. Wide bandgap semiconductors other than SiC, such as AlGaN, AlN and other nitride semiconductors, may also be used. Note that the material of the first semiconductor layer is not limited to wide bandgap semiconductors but can also be a semiconductor material with a relatively small bandgap, such as Si, for example. A sufficiently large thickness will reduce the electric field strength in the first semiconductor layer and suppress voltage breakdown. Si, especially polycrystalline Si, is easy to deposit and forms an interface of good electrical properties with few defects with an insulating film, particularly with silicon oxide. In the example shown in FIG. 12A, when a negative charge is trapped in a defect level at the interface, the Ec at the interface rises, making it harder for the tunnel current 1202 to flow during the negative charge injection shown in FIG. 12B, but this problem can be avoided by using a semiconductor with excellent interface properties such as Si. The first semiconductor layer may be a stacked film of multiple different semiconductor materials. For example, a thin semiconductor layer with good interface properties such as Si may be inserted in the area in contact with the third insulating film, with the other areas being wide bandgap semiconductors such as SiC. This provides both good interface properties and high breakdown field strength.

Next, the effects of the second invention of the present application will be explained. According to the second invention of the present application, the first capacitor used for charge accumulation on the charge-accumulation gate electrode is formed between the charge-accumulation gate electrode and the source or drain electrode, thus making an individual electrode for charge injection unnecessary and reducing the four electrodes required to operate the FET in the prior art to three. This simplifies the external circuit used to operate the FET as well as the FET manufacturing process, and reduces the area occupied by the FET on a substrate.

According to the third invention of the present application, even if the accumulated charge flows out of one of the multiple separated charge-accumulation gate electrodes, the local threshold voltages of the remaining charge-accumulation gate electrodes remain unchanged, thus allowing the normally-off state to be easily maintained. This results in a longer lifetime as a normally-off FET and minimizes device malfunctions due to the change to normally-on while in use as a switch.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a plan view and cross-sectional views showing the structure of the field-effect transistor device according to the first invention of the present application.

FIG. 2 is a plan view and cross-sectional views showing the structure of the field-effect transistor device according to the first invention of the present application.

FIG. 3 is a plan view and cross-sectional views showing the structure of the field-effect transistor device according to the second invention of the present application.

FIG. 4 is a plan view and cross-sectional views showing the structure of the field-effect transistor device according to the second invention of the present application.

FIG. 5 is a plan view and cross-sectional views showing the structure of the field-effect transistor device according to the second invention of the present application.

FIG. 6 is a plan view and cross-sectional views showing the structure of the field-effect transistor device according to the second invention of the present application.

FIG. 7 is a plan view and a cross-sectional view showing the structure of the field-effect transistor device according to the second invention of the present application.

FIG. 8 is a plan view and cross-sectional views showing the structure of the field-effect transistor device according to the third invention of the present application.

FIG. 9 is a plan view and cross-sectional views showing the structure of the field-effect transistor device according to the third invention of the present application.

FIG. 10 is a plan view and cross-sectional views showing the structure of the prior field-effect transistor device.

FIG. 11A is a schematic view of a portion of the prior field-effect transistor device.

FIG. 11B is an energy diagram of the lower end of the conduction band and the upper end of the valence band along the points A, B and C in the prior field-effect transistor device shown in FIG. 11A.

FIG. 11C is an energy diagram of the lower end of the conduction band and the upper end of the valence band along the points A, B and D in the prior field-effect transistor device shown in FIG. 11A.

FIG. 11D is an energy diagram of the lower end of the conduction band and the upper end of the valence band along the points A, B and C in the prior field-effect transistor device shown in FIG. 11A.

FIG. 11E is an energy diagram of the lower end of the conduction band and the upper end of the valence band along the points A, B and D in the prior field-effect transistor device shown in FIG. 11A.

FIG. 11F is an energy diagram of the lower end of the conduction band and the upper end of the valence band along the points A, B and D in the prior field-effect transistor device shown in FIG. 11A.

FIG. 12A is a schematic view of a portion of the field-effect transistor device according to the first invention of the present application.

FIG. 12B is an energy diagram of the lower end of the conduction band and the upper end of the valence band along the points A, B and D in the field-effect transistor device according to the first invention of the present application shown in FIG. 12A.

FIG. 12C is an energy diagram of the lower end of the conduction band and the upper end of the valence band along the points A, B and D in the field-effect transistor device according to the first invention of the present application shown in FIG. 12A.

FIG. 13 is a graph showing the current-voltage characteristic of the first capacitor according to the first invention of the present application.

FIG. 14A is a schematic view of a portion of the field-effect transistor device according to the first invention of the present application.

FIG. 14B is an energy diagram of the lower end of the conduction band and the upper end of the valence band along the points A, B and D in the field-effect transistor device according to the first invention of the present application shown in FIG. 14A.

FIG. 14C is an energy diagram of the lower end of the conduction band and the upper end of the valence band along the points A, B and D in the field-effect transistor device according to the first invention of the present application shown in FIG. 14A.

When the terms “front”, “rear”, “left”, “right”, “up”, “down”, “top”, “bottom”, “inner”, “outer”, “side”, and similar terms are used herein, it should be understood that these terms have reference only to the structure shown in the drawings as it would appear to a person viewing the drawings and are utilized only to facilitate describing the invention, rather than restricting the invention.

### DETAILED DESCRIPTION OF THE INVENTION

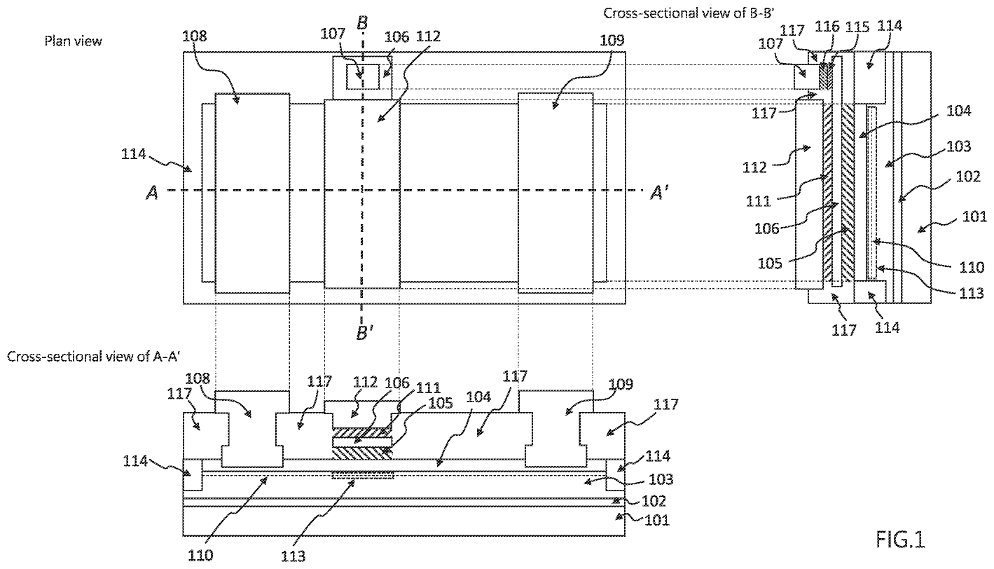

The following is a description of the embodiments of the invention of the present application with reference to the drawings. FIG. 1 is a view showing the structure of the field-effect transistor device according to an embodiment of the first invention of the present application. A buffer layer 102, a first nitride semiconductor layer 103 and a second nitride semiconductor layer 104 are deposited one by one on a substrate 101. Si, GaN, sapphire, SiC and the like may be used as a substrate. The bandgap of at least a portion of the second nitride semiconductor layer 104 is wider than that of at least a portion of the first nitride semiconductor layer 103. This forms a conduction channel 110 on the side of the first nitride semiconductor layer 103 at the interface between the first nitride semiconductor layer 103 and the second nitride semiconductor layer 104. For example, GaN is used for the first nitride semiconductor layer 103 and AlGaN for the second nitride semiconductor layer 104. When the composition of AlGaN is described as AlxGa₁₋ₓN, x satisfies the relationship 0<x≤1. Other nitride semiconductor materials such as InN, ScN or a mixed crystal of these nitride semiconductors may be used. A charge-accumulation gate electrode 106 is formed on a first insulating film 105 above the first nitride semiconductor layer 104. The capacitor formed between the conduction carrier 113 of the gate electrode portion, which is formed in the conduction channel 110 below the charge-accumulation gate electrode 106, and the charge-accumulation gate electrode 106 is called a third capacitor. A gate electrode 112 is formed on a second insulating film 111 above the charge-accumulation gate electrode 106. The capacitor formed between the gate electrode 112 and the charge-accumulation gate electrode 106 is called a second capacitor. A source electrode 108 and a drain electrode 109 are formed horizontally with the charge-accumulation gate electrode 106 in between. Both the source electrode 108 and the drain electrode 109 are electrically connected to the conduction channel 110 within the area surrounded by a device separation region 114. The gate electrode 112 is capacitively coupled to the conduction carrier 113 of the gate electrode portion via the second and third capacitors connected in series. The voltage applied to the gate electrode 112 changes the number of carriers in the conduction carrier 113 of the gate electrode portion, thereby regulating the current flowing between the source electrode 108 and the drain electrode 109, providing operation as a field-effect transistor (FET). The charge-accumulation gate electrode 106, the gate electrode 112, the source electrode 108 and the drain electrode 109 all include metallically connected portions on the substrate 101. Therefore, each of these electrodes is not necessarily formed in a single process but may be formed by a metallic contact of films formed in multiple processes. This is also the case in other embodiments of the first invention of the present application. The film material may be a conventional single metal, an alloy, a compound metal, a low-resistance semiconductor such as polysilicon doped with a high concentration of impurities or a combination of these materials. This is also the case in other embodiments of the first invention of the present application. Then, a third insulating film 115, a first semiconductor layer 116 and a charge-injection electrode 107 are formed one by one on the charge-accumulation gate electrode 106. This part is the characteristic portion of the embodiment as the first invention of the present application. The capacitor formed between the charge-injection electrode 107 and the charge-accumulation gate electrode 106 is called a first capacitor. The peripheral portions of the first, second and third capacitors are protected by a protective insulating film 117. The protective insulating film 117 may be the insulating film that forms the first, second and third capacitors, or a different insulating film may be used. The first capacitor is used to accumulate a charge on the charge-accumulation gate electrode 106. The method will be described in [0059]. The materials for the first insulating film 105, the second insulating film 111 and the third insulating film 115 may be conventionally known insulating film materials, such as silicon oxide, silicon nitride, silicon oxynitride, alumina, hafnia, zirconia, or a stacked film or a mixed film of these materials. The material for the first semiconductor layer 116 may be a conventionally known semiconductor material, such as silicon, silicon carbide, nitride, or a stacked film or a mixed film of these materials. The semiconductor layer may be either monocrystalline or polycrystalline. As described in [0030], silicon carbide has a wide bandgap and high breakdown field strength, making it suitable for the purpose of preventing the reverse flow of the charge accumulated on the charge-accumulation gate electrode 106. In contrast, polycrystalline silicon is preferred because it can be easily formed as a thin film and provides a good interface with few trap levels when silicon oxide is used as the third insulating film 115. Although silicon has a narrow bandgap and low breakdown field strength, the desirable breakdown voltage can be obtained by making it sufficiently thick. Alternatively, thin silicon may be used for the contact areas with the third insulating film 115, and a material with a wide bandgap, such as silicon carbide, for the other areas, providing a structure with excellent interface properties and breakdown voltage. The first semiconductor layer 116 is made n-type conductive so that the electrical contact with the charge-injection electrode 107 is ohmic or near ohmic with low resistance. The concentration of n-type impurities in the first semiconductor layer 116 may be uniform, or sloped with a low concentration on the side of the third insulating film 115 and a high concentration on the opposite side. When sloped, it provides low-resistance electrical contact with the charge-injection electrode 107 while ensuring breakdown voltage. Alternatively, when a material that generates a polarized charge is used for the first semiconductor layer 116, a thin layer with a high concentration of impurities may be introduced for the purpose of canceling the polarized charge. The material for the charge-injection electrode 107 may be a known single metal, an alloy, a compound metal, a semiconductor such as n-type polysilicon doped with a high concentration of impurities, or a combination of these materials. The materials for the third insulating film 115, the first semiconductor layer 116 and the charge-injection electrode 107 are the same in other embodiments of the first invention of the present application.

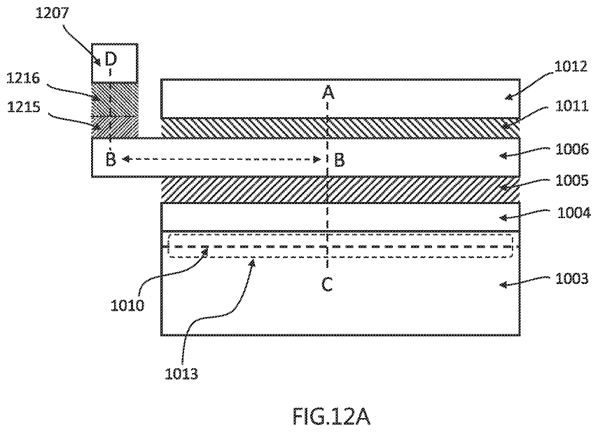

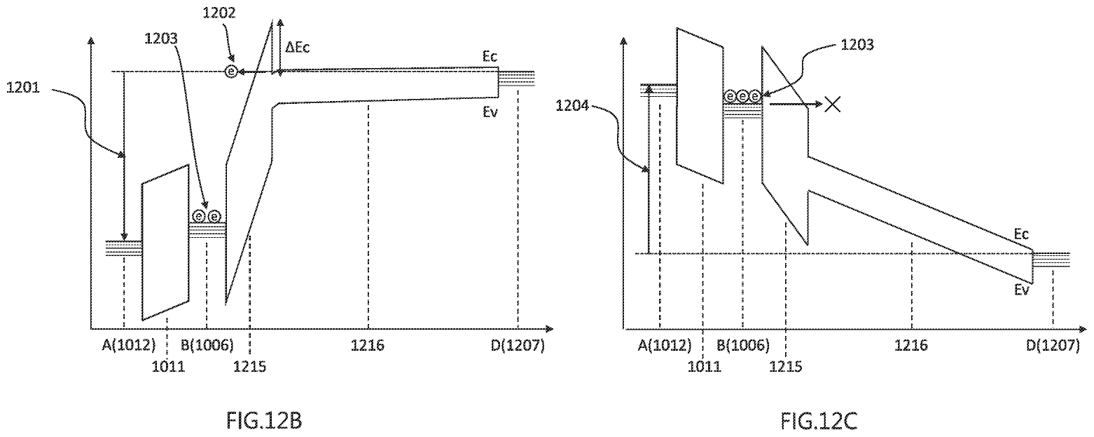

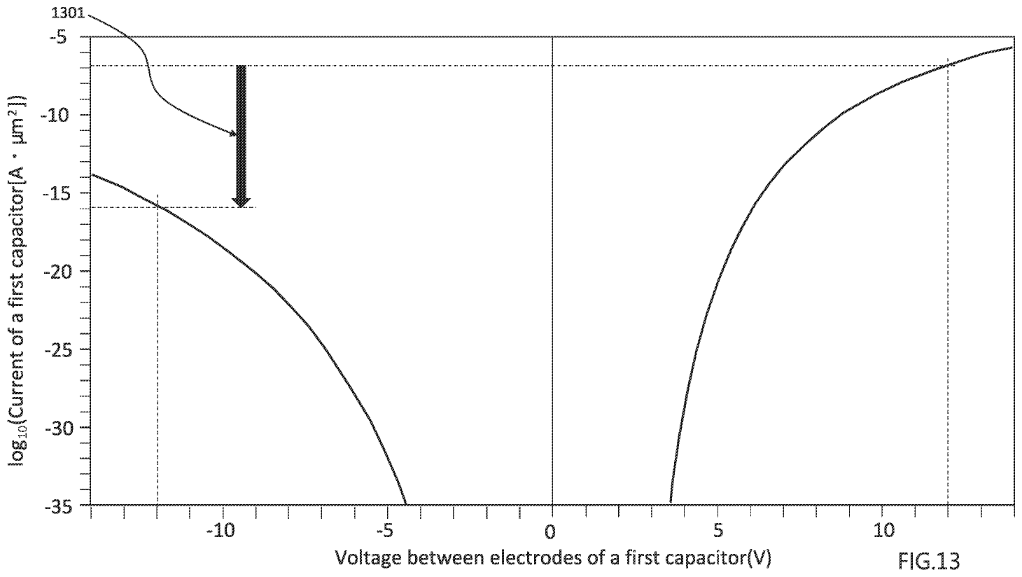

The threshold voltage control method in the embodiment of the first invention of the present application shown in FIG. 1 will be explained. The following method is to shift the threshold voltage in the positive direction to make the FET normally-off. A negative charge is accumulated on the charge-accumulation gate electrode 106 by a small current flowing through the first capacitor with the charge-injection electrode 107 as one of the electrodes. The charge-accumulation gate electrode 106 is a floating electrode, and the accumulated negative charge raises the potential energy of electrons and reduces the number of carriers in the conduction carrier 113 of the gate electrode portion. Accumulating a negative charge on the charge-accumulation gate electrode 106 until the conduction carrier 113 of the gate electrode portion substantially runs out of carriers when the voltage of the gate electrode 112 measured with reference to the source electrode 108 is zero or positive makes the threshold voltage a positive value and realizes normally-off operation. To accumulate a negative charge on the charge-accumulation gate electrode 106 using the first capacitor, a positive voltage may be applied to the gate electrode 112 with reference to the charge-injection electrode 107. For example, the voltage on the charge-injection electrode 107 is set to zero and the voltage on the gate electrode 112 is set to positive. Then the potential of the charge-accumulation gate electrode 106 also changes according to the voltage of the gate electrode 112 due to capacitive coupling with the second capacitor, rising higher than the potential of the charge-injection electrode 107. In other words, the potential energy for conduction electrons becomes lower at the charge-accumulation gate electrode 106 than at the charge-injection electrode 107. As a result, conduction electrons tunnel through the third insulating film 115, reaching the charge-accumulation gate electrode 106, where a negative charge is accumulated. The charge-injection electrode 1207 in FIG. 12A, which illustrates the principle of the first invention of the present application, corresponds to the charge-injection electrode 107 in this embodiment, and the energy of the lower end of the conduction band and the upper end of the valence band is as shown in FIG. 12B. The current during charge injection corresponds to the current in the positive voltage region in FIG. 13. Here, the areas of the gate electrode 112 and the charge-injection electrode 107 as well as the dielectric constants and thicknesses of the second and third insulating films 111 and 115 are selected so that the first capacitor is sufficiently smaller than the second capacitor. The voltage applied to the two series-connected capacitors is distributed in inverse proportion to their respective capacitances, allowing a higher voltage to be applied to the first capacitor than to the second capacitor. As a result, tunneling through the third insulating film 115 can easily occur, enabling an efficient injection of a negative charge into the charge-accumulation gate electrode 106. When an FET is used as a power switch, the static voltage of the gate electrode 112 during switch-off is zero volts, and furthermore, the various reactance components in the FET and switch drive circuit may cause dynamic voltage fluctuations, resulting in a negative dynamic voltage at the gate electrode 112. When the charge-injection electrode 107 is connected to the gate drive circuit through an external terminal, it is difficult to completely isolate the charge-injection electrode 107, leaving a leakage path to the ground potential during switch operation. Therefore, when the voltage of the gate electrode 112 is negative, the voltage of the charge-accumulation gate electrode 106 also becomes negative due to the capacitive coupling with the second capacitor, causing a reverse voltage to the first capacitor from that during the negative charge accumulation. In a prior FET, this causes a reverse current due to tunneling of the accumulated negative charge, resulting in a short holding time of the positive threshold voltage required for normally-off operation. In this embodiment of the first invention of the present application, however, inserting the first semiconductor layer 116 between the third insulating film 115 and the charge-injection electrode 107 distributes the voltage to the third insulating film 115 and the first semiconductor layer 116 as in the case shown in FIG. 12C, resulting in a lower voltage to the third insulating film 115. As shown in FIG. 13, the current in the negative voltage region is smaller than in the positive voltage region, which suppresses the reverse flow of the negative charge accumulated on the charge-accumulation gate electrode 106. As a result, the positive threshold voltage required for the normally-off operation can be maintained for a long duration.

In the embodiment shown in FIG. 1, the third insulating film 115 is provided on the side of the charge-accumulation gate electrode 106 and the first semiconductor layer 116 on the side of the charge-injection electrode 107 as for the part configuring the first capacitor, and the first semiconductor layer 116 is n-type. This is the same as the layer structure shown in FIG. 12A, but as with the structure shown in FIG. 15A, the third insulating film 115 may be provided on the side of the charge-injection electrode 107 and the first semiconductor layer 116 on the side of the charge-accumulation gate electrode 106, with the first semiconductor layer 116 being p-type. As described in FIGS. 15A, 15B and 15C, this case has the same effects as the structure shown in FIG. 1.

In the above embodiment of the first invention of the present application, the nitride semiconductor layer comprises the first nitride semiconductor layer 103 and the second nitride semiconductor layer 104, and the conduction channel 110 formed on the side of the first nitride semiconductor layer 103 at the interface between the first and second nitride semiconductor layers 103 and 104 provides a current path between the source electrode 108 and the drain electrode 109. In the FET in this embodiment, since conduction carriers are induced in the conduction channel 110 using the polarization charge generated by the difference in composition between the first nitride semiconductor layer 103 and the second nitride semiconductor layer 104, a large number of conduction carriers are spontaneously generated even without an externally applied voltage. This makes the FET normally-on with a very high negative threshold voltage. Therefore, a very large amount of negative charge is required to accumulate on the charge-accumulation gate electrode 106 to make the FET normally-off, leaving a serious problem of the reverse flow of the accumulated negative charge to the charge-injection electrode 107. The first invention of the present application can suppress this reverse flow and is particularly effective for nitride semiconductor FETs using the conduction channel 110 formed at the interface between the first nitride semiconductor layer 103 and the second nitride semiconductor layer 104, or HEMT, as shown in the FET in this embodiment. Note that the first invention of the present application is not limited to HEMTs. For example, the same effects can be obtained in an FET in which the second nitride semiconductor layer 114 is eliminated, the first insulating film 105 is formed directly on the first nitride semiconductor layer 103, and the conduction channel generated on the side of the first nitride semiconductor layer 103 at the interface between the first nitride semiconductor layer 103 and the first insulating film 105 is used as a current path flowing between the source electrode 108 and the drain electrode 109. This is also the case in other embodiments of the present application.

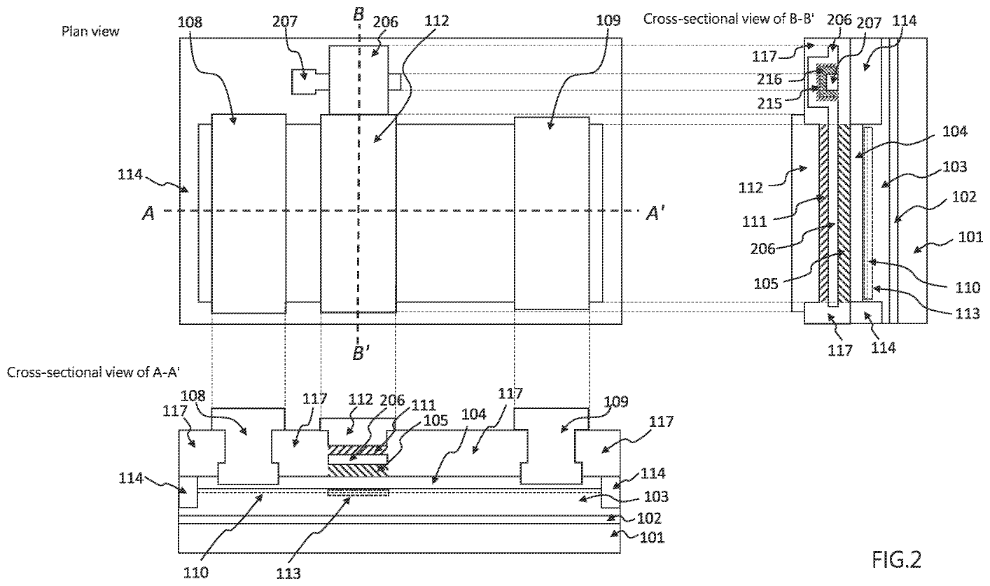

FIG. 2 shows another embodiment of the first invention of the present application. The difference of this embodiment from the embodiment shown in FIG. 1 is that the charge-injection electrode 207 forming the first capacitor is arranged closer to the substrate 101 than the charge-accumulation gate electrode 206. The third insulating film 215 is provided on the side of the charge-accumulation gate electrode 206 and the first semiconductor layer 216 on the side of the charge-injection electrode 207 in the same way as in the embodiment shown in FIG. 1. The conductivity type of the first semiconductor layer 216 is n-type. The structure in this embodiment can be obtained, for example, by first forming the charge-injection electrode 207, then sequentially forming the first semiconductor layer 216 and the third insulating film 215, followed by the formation of the charge-accumulation gate electrode 206. As in the embodiment shown in FIG. 1, when a negative voltage is applied to the gate electrode 112, the voltage applied between the charge-accumulation gate electrode 206 and the charge-injection electrode 207 is distributed to the third insulating film 215 and the first semiconductor layer 216, resulting in a lower voltage to the third insulating film 215. This makes it harder for the negative charge accumulated on the charge-accumulation gate electrode 206 to flow in the reverse direction, allowing the positive threshold voltage required for the normally-off operation to be maintained for a long duration. In this embodiment, the first capacitor is formed to include the upper edge of the charge-injection electrode 207. Since the electric field is concentrated at the edge, a smaller potential difference can generate a tunnel current, facilitating the injection of a negative charge into the charge-accumulation gate electrode 206.

In the embodiment shown in FIG. 2, as in the embodiment shown in FIG. 1, the third insulating film 215 may be provided on the side of the charge-injection electrode 207 and the first semiconductor layer 216 on the side of the charge-accumulation gate electrode 206, with the first semiconductor layer 216 being p-type. In this case, the same effects as the structure shown in FIG. 2 can be obtained.

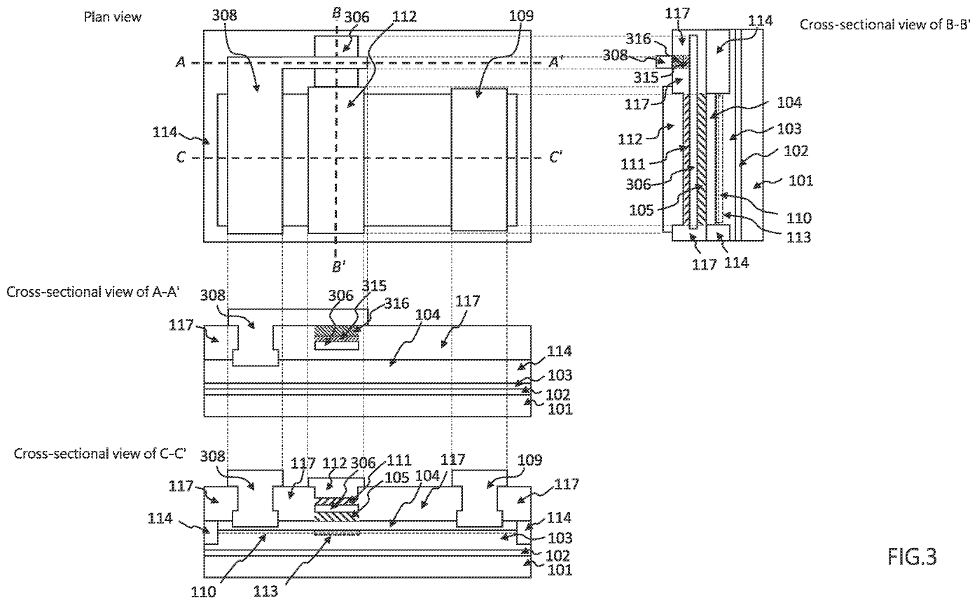

FIG. 3 is a view showing the structure of the field-effect transistor device according to an embodiment of the second invention of the present application. A buffer layer 102, a first nitride semiconductor layer 103 and a second nitride semiconductor layer 104 are deposited one by one on a substrate 101. Si, GaN, sapphire, SiC and the like may be used as a substrate. The bandgap of at least a portion of the second nitride semiconductor layer 104 is wider than that of at least a portion of the first nitride semiconductor layer 103. This forms a conduction channel 110 on the side of the first nitride semiconductor layer 103 at the interface between the first nitride semiconductor layer 103 and the second nitride semiconductor layer 104. For example, GaN is used for the first nitride semiconductor layer 103 and AlGaN for the second nitride semiconductor layer 104. When the composition of AlGaN is described as AlxGa₁₋ₓN, x satisfies the relationship 0<x≤1. Other nitride semiconductor materials such as InN, ScN or a mixed crystal of these nitride semiconductors may be used. A charge-accumulation gate electrode 306 is formed on a first insulating film 105 above the first nitride semiconductor layer 104. The capacitor formed between the conduction carrier 113 of the gate electrode portion, which is formed in the conduction channel 110 below the charge-accumulation gate electrode 306, and the charge-accumulation gate electrode 306 is called a third capacitor. A gate electrode 112 is formed on a second insulating film 111 above the charge-accumulation gate electrode 306. The capacitor formed between the gate electrode 112 and the charge-accumulation gate electrode 306 is called a second capacitor. A source electrode 308 and a drain electrode 109 are formed horizontally with the charge-accumulation gate electrode 306 in between. Both the source electrode 308 and the drain electrode 109 are electrically connected to the conduction channel 110 within the area surrounded by a device separation region 114. The gate electrode 112 is capacitively coupled to the conduction carrier 113 of the gate electrode portion via the second and third capacitors connected in series. The voltage applied to the gate electrode 112 changes the number of carriers in the conduction carrier 113 of the gate electrode portion, thereby regulating the current flowing between the source electrode 308 and the drain electrode 109, providing operation as a field-effect transistor (FET). The charge-accumulation gate electrode 306, the gate electrode 112, the source electrode 308 and the drain electrode 109 all include metallically connected portions on the substrate 101. Therefore, each of these electrodes is not necessarily formed in a single process but may be formed by a metallic contact of films formed in multiple processes. This is also the case in other embodiments of the second invention of the present application. The film material may be a conventional single metal, an alloy, a compound metal, a low-resistance semiconductor such as polysilicon doped with a high concentration of impurities, or a combination of these materials. This is also the case in other embodiments of the second invention of the present application. As an example of a method of forming the characteristic portion of the second invention of the present application, a portion of the source electrode 308 may be extended to overlap the opposite side of the charge-accumulation gate electrode 306 from the substrate 101, and a first capacitor may be formed by capacitive coupling with the charge-accumulation gate electrode 306. In this embodiment, a third insulating film 315 is provided on the side of the charge-accumulation gate electrode 306 and a first semiconductor layer 316 on the side of the source electrode 308 in the portion where the first capacitor is formed. The peripheral portions of the first, second and third capacitors are protected by a protective insulating film 117. The protective insulating film 117 may be the insulating film that forms the first, second and third capacitors, or a different insulating film may be used. The first capacitor is used to accumulate a charge on the charge-accumulation gate electrode 306. The method will be described in [0065]. The materials for the first insulating film 105, the second insulating film 11 and the third insulating film 315 may be conventionally known insulating film materials, such as silicon oxide, silicon nitride, silicon oxynitride, alumina, hafnia, zirconia, or a stacked film or a mixed film of these materials. The material for the first semiconductor layer 316 may be a conventionally known semiconductor material, such as silicon, silicon carbide, nitride, or a stacked film or a mixed film of these materials. The semiconductor layer may be either monocrystalline or polycrystalline. As described in [0030], silicon carbide has a wide bandgap and high breakdown field strength, making it suitable for the purpose of preventing the reverse flow of the charge accumulated on the charge-accumulation gate electrode 306. In contrast, polycrystalline silicon is preferred because it can be easily formed as a thin film and provides a good interface with few trap levels when silicon oxide is used as the third insulating film 315. Although silicon has a narrow bandgap and low breakdown field strength, the desirable breakdown voltage can be obtained by making it sufficiently thick. Alternatively, thin silicon may be used for the contact areas with the insulating film 315, and a material with a wide bandgap, such as silicon carbide, for the other areas, providing a structure with excellent interface properties and breakdown voltage. The first semiconductor layer 316 is made n-type conductive so that the electrical contact with the source electrode 308 is ohmic or near ohmic with low resistance. The concentration of n-type impurities in the first semiconductor layer 316 may be uniform, or sloped with a low concentration on the side of the third insulating film 315 and a high concentration on the opposite side. When sloped, it provides low-resistance electrical contact with the source electrode 308 while ensuring breakdown voltage. Alternatively, when a material that generates a polarized charge is used for the first semiconductor layer 316, a thin layer with a high concentration of impurities may be introduced for the purpose of canceling the polarized charge. The materials for the third insulating film 315 and the first semiconductor layer 316 are the same in other embodiments of the second invention of the present application.

The threshold voltage control method in the embodiment of the second invention of the present application shown in FIG. 3 will be explained. The following method assumes that the FET is normally-off with the threshold voltage shift in the positive direction. A negative charge is accumulated on the charge-accumulation gate electrode 306 by a small current flowing through the first capacitor with the source electrode 308 as one of the electrodes. The charge-accumulation gate electrode 306 is a floating electrode, and the accumulated negative charge raises the potential energy of electrons and reduces the number of carriers in the conduction carrier 113 of the gate electrode portion. Accumulating a negative charge on the charge-accumulation gate electrode 306 until the number of carriers in the conduction carrier 113 of the gate electrode portion substantially becomes zero even when the voltage of the gate electrode 112 measured with reference to the source electrode 308 is zero or positive, makes the threshold voltage a positive value and realizes normally-off operation. To accumulate a negative charge on the charge-accumulation gate electrode 306 using the first capacitor, a more positive voltage than the source electrode 308 may be applied to the gate electrode 112. For example, the voltage on the source electrode 308 is set to zero and the voltage on the gate electrode 112 is set to positive. In this case, the potential of the charge-accumulation gate electrode 306 is also higher than that of the source electrode 308 due to the capacitive coupling with the second capacitor. In other words, the potential energy for electrons becomes lower at the charge-accumulation gate electrode 306 than at the source electrode 308. As a result, conduction electrons tunnel through the third insulating film, reaching the charge-accumulation gate electrode 306, where a negative charge is accumulated. The prior FETs require an individual electrode for the accumulation of negative charge to the charge-accumulating gate electrode 306. In this embodiment of the second invention of the present application, however, the accumulation of negative charge to the charge-accumulating gate electrode 306 is performed from the source electrode 308. Therefore, the four electrodes required to operate an FET in the prior art can be reduced to three. This simplifies the external circuit used to operate the FET as well as the FET manufacturing process, and reduces the area occupied by the FET on a substrate. Note that the area of the gate electrode 112, and the area of the overlap portion of the source electrode 308 and the charge-accumulation gate electrode 306, as well as the dielectric constants and thicknesses of the second and third insulating films 111 and 315, are selected so that the capacitance of the first capacitor is sufficiently smaller than the capacitance of the second capacitor. The voltage applied to the two series-connected capacitors is distributed in inverse proportion to their respective capacitances, allowing a higher voltage to be applied to the first capacitor than to the second capacitor. As a result, tunneling through the third insulating film 315 can easily occur, enabling an efficient injection of a negative charge into the charge-accumulation gate electrode 306.

In the embodiment of the second invention of the present application shown in FIG. 3, the third insulating film 315 is provided on the side of the charge-accumulation gate electrode 306 and the first semiconductor layer 316 on the side of the source electrode 308 at the overlap portion of the source electrode 308 and the charge-accumulation gate electrode 306 forming the first capacitor. This structure is the same as that of the first capacitor of the first invention of the present application, corresponding to the case where the charge-injection electrode 1207 is replaced with a source electrode in FIGS. 12A, 12B and 12C. The lower end of the conduction band and the upper end of the valence band during the negative charge injection are the same as in FIG. 12B, and virtually the entire voltage between the source electrode 308 and the charge-accumulation gate electrode 306 is applied to the third insulating film 315, causing the negative charge to accumulate by tunneling through the third insulating film 315. When the FET in this embodiment is used as a switch, the static voltage at the gate electrode 112 is nearly zero with reference to the source electrode 308 during switch-off. In addition, the various reactance components in the FET and switch drive circuit may cause dynamic voltage fluctuations, resulting in a negative dynamic voltage at the gate electrode 112, also making the potential of the charge-accumulation gate electrode 306 negative due to the capacitive coupling by the second capacitor between the gate electrode 112 and the charge-accumulation gate electrode 306. In this case, since the electrode on the opposite side of the first capacitor from the charge-accumulation gate electrode 306 is the source electrode 308, a voltage is applied to the first capacitor in the opposite direction from that during the negative charge accumulation on the charge-accumulation gate electrode 306. In this embodiment, however, as in the first capacitor of the first invention of the present application, the voltage is distributed between the third insulating film 315 and the first semiconductor layer 316, resulting in a lower voltage to the third insulating film 315. This is also the case with the situation shown in FIG. 12C of the first invention of the present application. As a result, the reverse flow of the negative charge accumulated in the charge-accumulation gate electrode 306 due to tunneling can be suppressed, allowing the positive threshold voltage required for the normally-off operation to be maintained for a long duration.

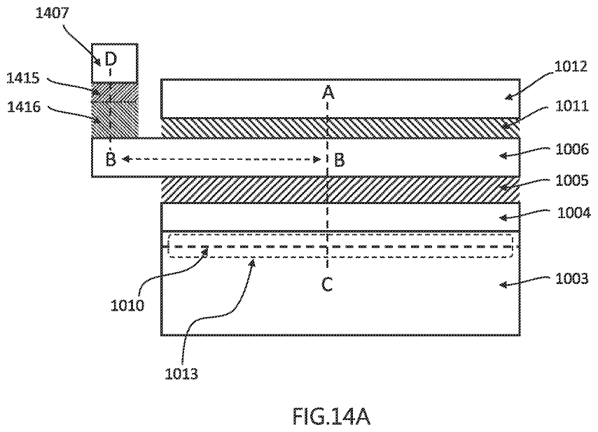

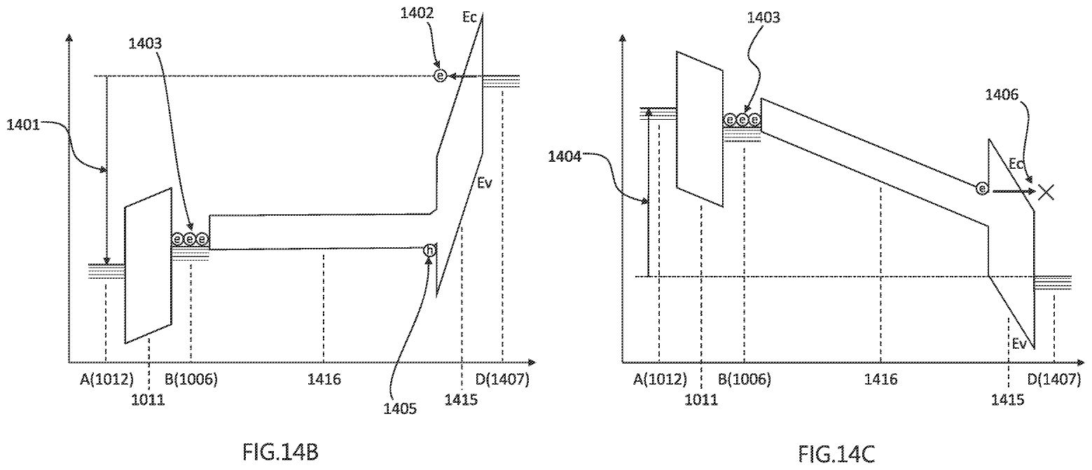

In another form of the embodiment shown in FIG. 3, the third insulating film 315 may be provided on the side of the source electrode 308 and the first semiconductor layer 316 on the side of the charge-accumulation gate electrode 306, with the first semiconductor layer 316 being p-type. This corresponds to the case where the charge-injection electrode 1407 is replaced with a source electrode in FIGS. 14A, 14B and 14C, resulting in the same effects as those of the structure shown in FIG. 3. Alternatively, the first capacitor may be formed by eliminating the first semiconductor layer 316 and using only the third insulating film 315. This increases the leakage of the negative charge accumulated on the charge-accumulation gate electrode 306, but the effects of the second invention of the present application of reducing the number of electrodes are obtained in the same way.

In the second invention of the present application, the first capacitor may be formed between the source or drain electrode and the charge-accumulation gate electrode. In the embodiment shown in FIG. 3, the first capacitor is formed between the source electrode and the charge-accumulation gate electrode. To accumulate a negative charge on the charge-accumulation gate electrode, a positive voltage needs to be applied to the charge-accumulation gate electrode with reference to the opposite electrode of the first capacitor, thus a positive voltage must be applied to the gate electrode with reference to the opposite electrode from the charge-accumulation gate electrode. A positive voltage is applied to the gate electrode with reference to the source electrode in a normal operation for a power switch. Therefore, using the source electrode as the electrode on the opposite side of the first capacitor from the charge-accumulation gate electrode makes it easier to design a drive circuit to accumulate a negative charge. Note that the same effects can be obtained by properly designing the drive circuit, etc., also in the case where the first capacitor is formed between the drain electrode and the charge-accumulation gate electrode. This is also the case in other embodiments of the second invention of the present application as well as in the corresponding embodiments of the third invention of the present application, which will be described later.

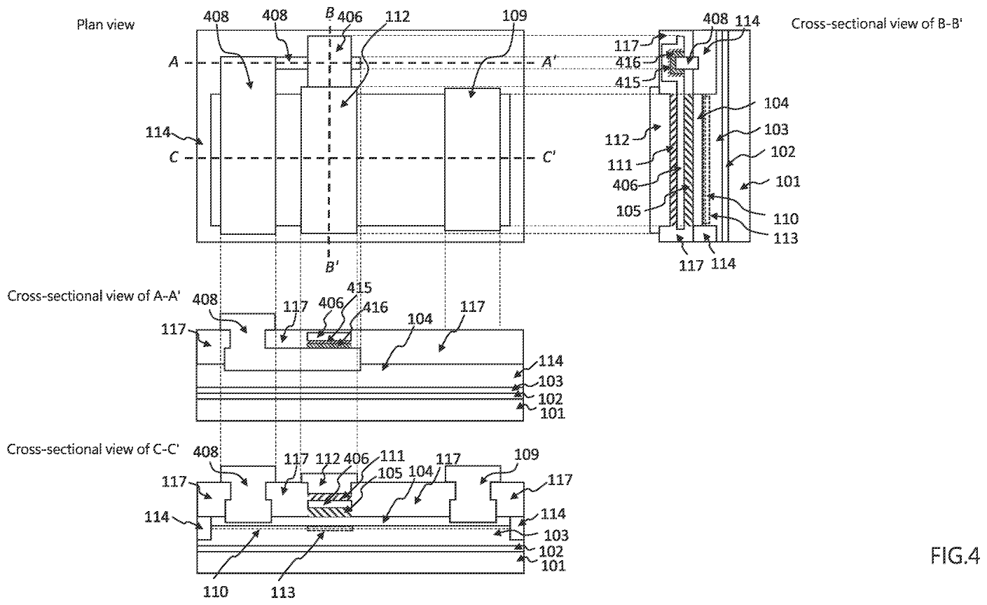

FIG. 4 shows another embodiment of the second invention of the present application. The difference of this embodiment from the embodiment shown in FIG. 3 is that the source electrode 408 is extended to the side of the substrate 101 not on the upper surface of the charge-accumulation gate electrode 406 at the portion forming the first capacitor. The first semiconductor layer 416 is provided on the side of the source electrode 408 and the third insulating film 415 on the side of the charge-accumulation gate electrode 406 in the portion where the first capacitor is formed, with the first semiconductor layer 416 being n-type. The structure of the other parts of the FET, the method of making the FET normally-off, the effects of using the FET as a switch and similar alternative forms are the same as in the embodiment shown in FIG. 3 described in [0065], [0066], [0067] and [0068]. In this embodiment, the charge-accumulation gate electrode 406 is provided over the source electrode 408 to form the first capacitor, and the top edge of the film forming the source electrode 408 is included in the structure of the first capacitor. Since the electric field is likely to be concentrated at the electrode edge, tunneling can easily occur, making the accumulation of a negative charge on the charge-accumulation gate electrode 406 more efficient.

FIG. 5 shows another embodiment of the second invention of the present application. The difference of this embodiment from the embodiment shown in FIG. 3 is that the source electrode 508 is not extended to the charge-accumulation gate electrode 506, but the charge-accumulation gate electrode 506 is extended to the source electrode 508 to form the first capacitor. The first semiconductor layer 516 is provided on the side of the source electrode 508 and the third insulating film 515 on the side of the charge-accumulation gate electrode 506 in the portion where the first capacitor is formed, with the first semiconductor layer 516 being n-type. The structure of the other parts of the FET, the method of making the FET normally-off, the effects of using the FET as a switch and similar alternative forms are the same as in the embodiment shown in FIG. 3 described in [0065], [0066], [0067] and [0068].

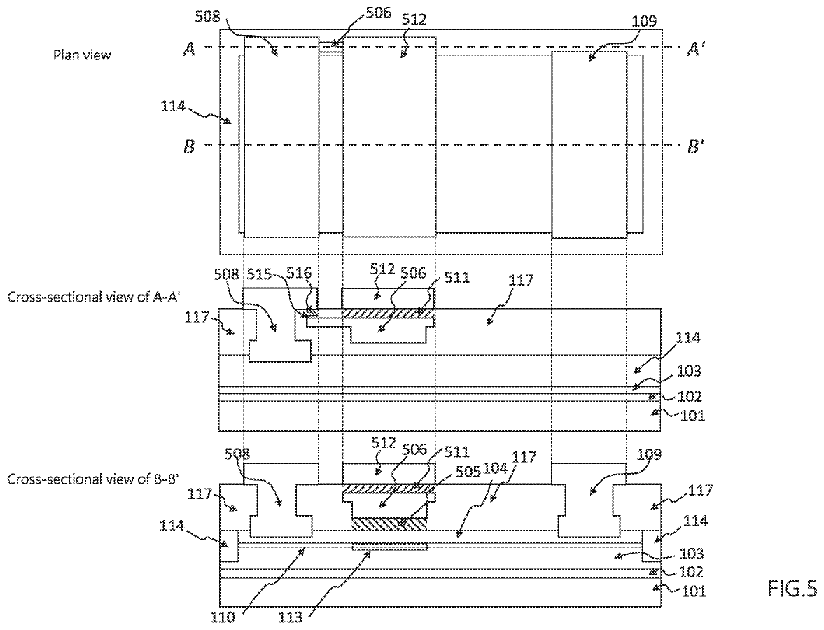

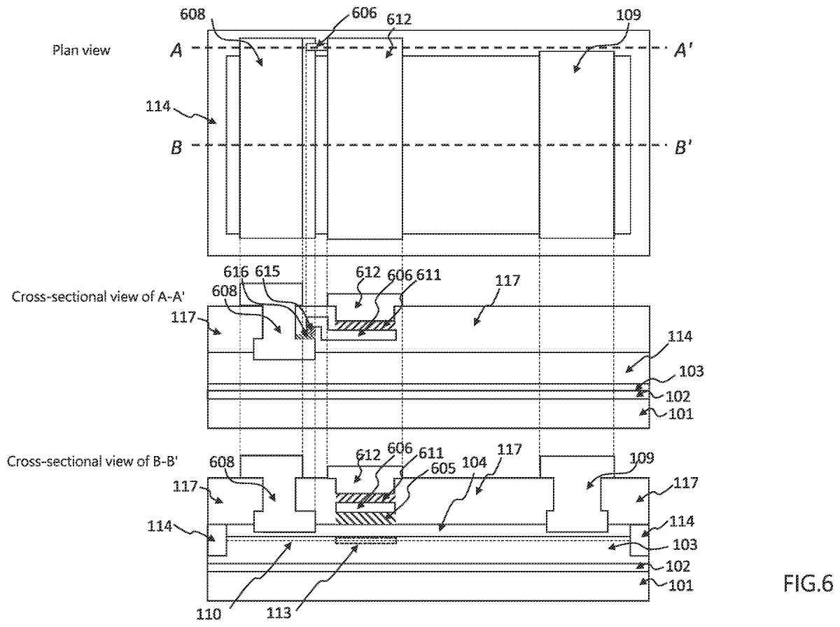

FIG. 6 shows another embodiment of the second invention of the present application. The difference of this embodiment from the embodiment shown in FIG. 3 is that the source electrode 608 is not extended to the charge-accumulation gate electrode 606, but the charge-accumulation gate electrode 606 is extended to the source electrode 608 to form the first capacitor. The difference from the embodiment shown in FIG. 5 is that the charge-accumulation gate electrode 606 is extended so that it is provided over the source electrode 608. The first semiconductor layer 616 is provided on the side of the source electrode 608 and the third insulating film 615 on the side of the charge-accumulation gate electrode 606 in the portion where the first capacitor is formed. The structure of the other parts of the FET, the method of making the FET normally-off, the effects of using the FET as a switch and similar alternative forms are the same as in the embodiment shown in FIG. 3 described in [0065], [0066], [0067] and [0068].

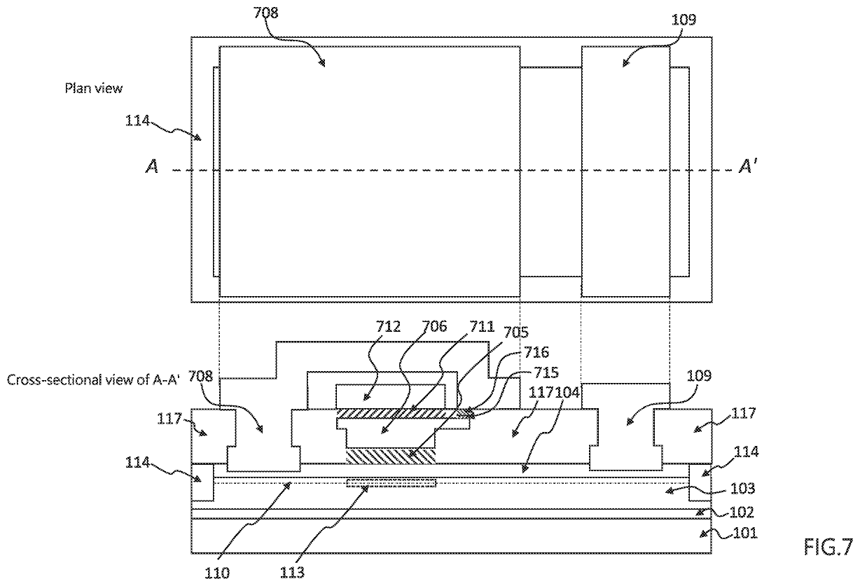

FIG. 7 shows another embodiment of the second invention of the present application. The difference of this embodiment from the embodiment shown in FIG. 3 is that the source electrode 708 is extended beyond the gate electrode 712 to the side of the drain electrode 109, forming the first capacitor with the charge-accumulation gate electrode 706. The first semiconductor layer 716 is provided on the side of the source electrode 708 and the third insulating film 715 on the side of the charge-accumulation gate electrode 706 in the portion where the first capacitor is formed. The structure of the other parts of the FET, the method of making the FET normally-off, the effects of using the FET as a switch and similar alternative forms are the same as in the embodiment shown in FIG. 3 described in [0065], [0066], [0067] and [0068]. In this embodiment, the source electrode 708 that is extended beyond the charge-accumulation gate electrode 706 to the side of the drain electrode 109 functions also as a so-called field plate, and when a high voltage is applied to the drain electrode 109, most of the voltage is applied between the extended source electrode 708 and the drain electrode 109, suppressing the electric field concentration at the edge of the charge-accumulation gate electrode 706 on the side of the drain electrode 109. This prevents the outflow of the accumulated charge on the charge-accumulation gate electrode 706, which tends to occur in areas where the electric field is concentrated, and the resulting shortening of the lifetime as a normally-off FET. In the embodiment shown in FIG. 7, the source electrode 708 is capacitively coupled across the entire portion in the direction perpendicular to A-A′ at the end of the charge-accumulation gate electrode 706 on the side of the drain electrode 109 to form the first capacitor, but the portion of capacitive coupling may be limited to a portion in the direction perpendicular to A-A′, and the portion of capacitive coupling may be formed on the device separation region 114. This makes the first capacitor smaller and allows a higher voltage to be applied to the first capacitor during the negative charge injection, making the negative charge injection more efficient.

FIG. 8 is a view showing the structure of the field-effect transistor device according to an embodiment of the third invention of the present application. A buffer layer 102, a first nitride semiconductor layer 103 and a second nitride semiconductor layer 104 are deposited one by one on a substrate 101. Si, GaN, sapphire, SiC and the like may be used as a substrate. The bandgap of at least a portion of the second nitride semiconductor layer 104 is wider than that of at least a portion of the first nitride semiconductor layer 103. This forms a conduction channel 110 on the side of the first nitride semiconductor layer 103 at the interface between the first nitride semiconductor layer 103 and the second nitride semiconductor layer 104. For example, GaN is used for the first nitride semiconductor layer 103 and AlGaN for the second nitride semiconductor layer 104. When the composition of AlGaN is described as AlxGa₁₋ₓN, x satisfies the relationship 0<x≤1. Other nitride semiconductor materials such as InN, ScN or a mixed crystal of these nitride semiconductors may be used. As a characteristic part of the third invention of the present application, charge-accumulation gate electrodes 806 divided into multiple strips are provided on a first insulating film 805 above the first nitride semiconductor layer 104. The coupling capacitance between the conduction carrier 813 of the gate electrode portion, which is formed in the conduction channel 110 below the charge-accumulation gate electrode 806, and the charge-accumulation gate electrode 806 is called a third capacitor. A gate electrode 812 is formed on a second insulating film 811 above the charge-accumulation gate electrode 806. The coupling capacitance between the gate electrode 812 and the charge-accumulation gate electrode 806 is called a second capacitor. A source electrode 808 and a drain electrode 109 are formed horizontally with the charge-accumulation gate electrode 806 in between. Both the source electrode 808 and the drain electrode 109 are electrically connected to the conduction channel 110 within the area surrounded by a device separation region 114. In this embodiment, the charge-accumulation gate electrodes 806 divided into multiple strips are all arranged to intersect the direction of the current flowing between the source electrode 808 and the drain electrode 109. The gate electrode 812 is capacitively coupled to the conduction carrier 813 of the gate electrode portion via the second and third capacitors connected in series. The voltage applied to the gate electrode 812 changes the number of carriers in the conduction carrier 813 of the gate electrode portion, thereby regulating the current flowing between the source electrode 808 and the drain electrode 109, providing operation as a field-effect transistor (FET). The charge-accumulation gate electrode 806, the gate electrode 812, the source electrode 808 and the drain electrode 109 all include metallically connected portions on the substrate 101. Therefore, each of these electrodes is not necessarily formed in a single process but may be formed by a metallic contact of films formed in multiple processes. This is also the case in other embodiments of the third invention of the present application. The film material may be a conventional single metal, an alloy, a compound metal, a low-resistance semiconductor such as polysilicon doped with a high concentration of impurities, or a combination of these materials. This is also the case in other embodiments of the third invention of the present application. A part of the source electrode 808 is extended to overlap any of the multiple charge-accumulation gate electrodes 806, and a first capacitor is formed by capacitive coupling between the source electrode 808 and the charge-accumulation gate electrode 806. A third insulating film 815 is provided on the side of the charge-accumulation gate electrode 806 and a first semiconductor layer 816 on the side of the source electrode 808 in the portion where the first capacitor is formed. The peripheral portions of the first, second and third capacitors are protected by a protective insulating film 117. The protective insulating film 117 may be the insulating film that forms the first, second and third capacitors, or a different insulating film may be used. The first capacitor is used to accumulate a charge on the charge-accumulation gate electrode 806. The materials for the first insulating film 805, the second insulating film 811 and the third insulating film 815 may be conventionally known insulating film materials, such as silicon oxide, silicon nitride, silicon oxynitride, alumina, hafnia, zirconia, or a stacked film or a mixed film of these materials. The material for the first semiconductor layer 816 may be a conventionally known semiconductor material, such as silicon, silicon carbide, nitride, or a stacked film or a mixed film of these materials. The semiconductor layer may be either monocrystalline or polycrystalline. As described in [0030], silicon carbide is preferred because of its wide bandgap and high breakdown field strength. In contrast, polycrystalline silicon is preferred because it can be easily formed as a thin film and provides a good interface with few trap levels when silicon oxide is used as the third insulating film 815. Although silicon has a narrow bandgap and low breakdown field strength, the desirable breakdown voltage can be obtained by making it sufficiently thick. Alternatively, thin silicon may be used for the contact areas with the insulating film 815, and a material with a wide bandgap, such as silicon carbide, for the other areas, providing a structure with excellent interface properties and breakdown voltage. The first semiconductor layer 816 is made n-type conductive so that the electrical contact with the source electrode 808 is ohmic or near ohmic with low resistance. The concentration of n-type impurities may be uniform, or sloped with a low concentration on the side of the third insulating film 815 and a high concentration on the opposite side. When sloped, it provides low-resistance electrical contact with the source electrode 808 while ensuring breakdown voltage. Alternatively, when a material that generates a polarized charge is used for the first semiconductor layer 816, a thin layer with a high concentration of impurities may be introduced for the purpose of canceling the polarized charge. In this embodiment according to the third invention, since the charge-accumulation gate electrodes 806 comprise multiple electrodes that intersect the direction of the current flowing between the source electrode 808 and the drain electrode 109, even when the current leakage caused by a defect, etc., in the first, second or third capacitor connected to any one of the charge-accumulation gate electrodes 806 leads to an outflow of accumulated electric charge, or even when the electric field is concentrated at any one place to cause a current leakage due to tunneling and an outflow of accumulated electric charge, the threshold voltage of the FET itself is hardly affected because the rest of the charge-accumulation gate electrodes 806 are not affected. This results in a longer lifetime of the FET that is made normally-off by controlling the threshold voltage to a positive value as a normally-off FET. It also prevents device failures due to the shift to normally-on during operation.

The FET shown in FIG. 8 is the same as the FET shown in FIG. 4 except that the charge-accumulation gate electrodes 806 comprise multiple strips, and is also functionally equivalent to the FET shown in FIG. 3. Therefore, the structure of the other parts of the FET, the method of making the FET normally-off, the effects of using the FET as a switch and similar alternative forms are the same as in the embodiment shown in FIG. 3 described in [0065], [0066], [0067] and [0068]. Since the first capacitor is formed by capacitive coupling between the charge-accumulation gate electrode 806 and the source electrode 808, no individual electrode is needed for the negative charge accumulation on the charge-accumulation gate electrode 808 due to the first capacitor. In other words, the second invention of the present application is applied in the same way as the FETs shown in FIGS. 3 and 4. This simplifies the external circuit used to operate the FET as well as the FET manufacturing process and reduces the area occupied by FETs on a substrate. Note that, in another form, the first capacitor may be formed with a charge-injection electrode that is separately provided. In this case, a single charge-injection electrode may be provided for the charge-accumulation gate electrodes 806 divided into multiple strips, or the charge injection electrode may also be provided in a multiple form.

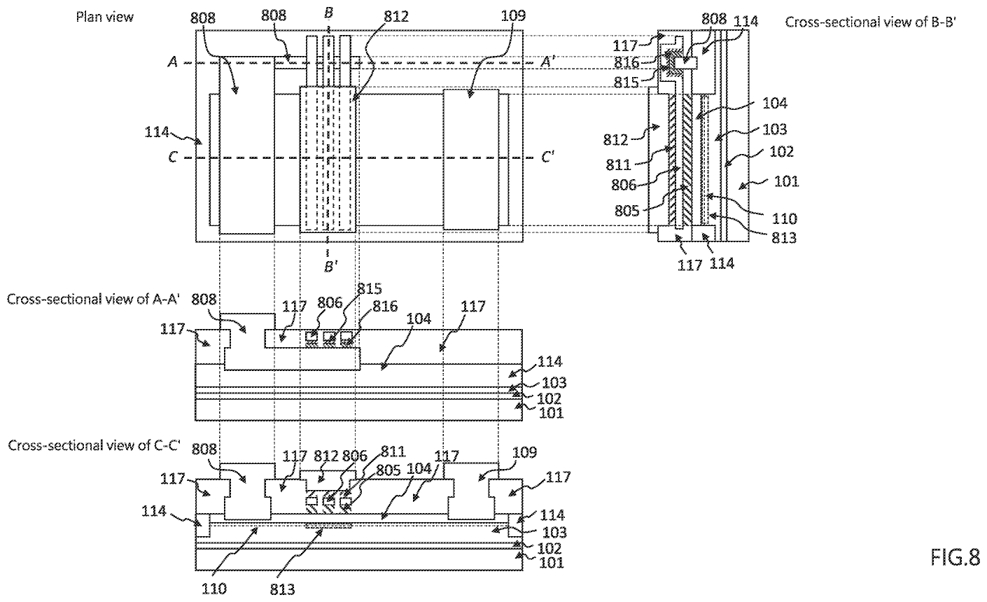

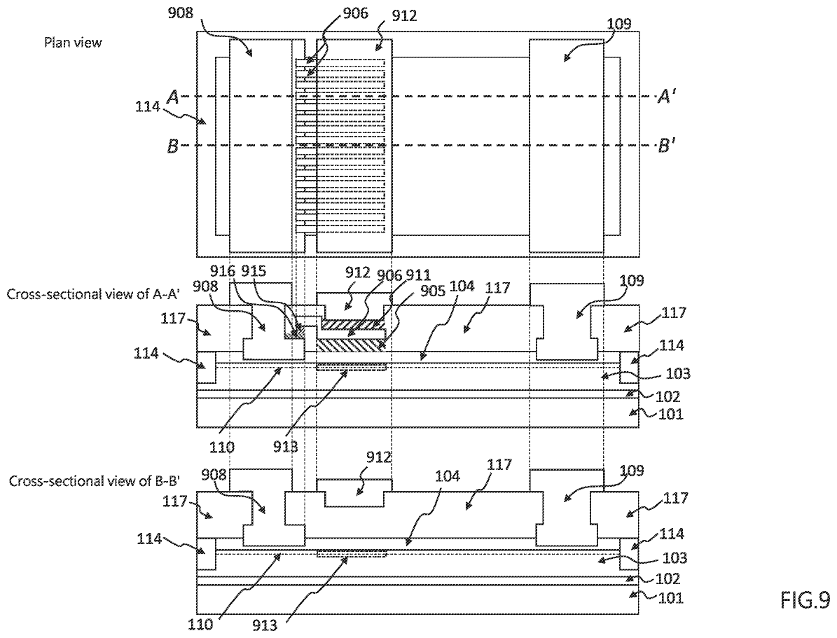

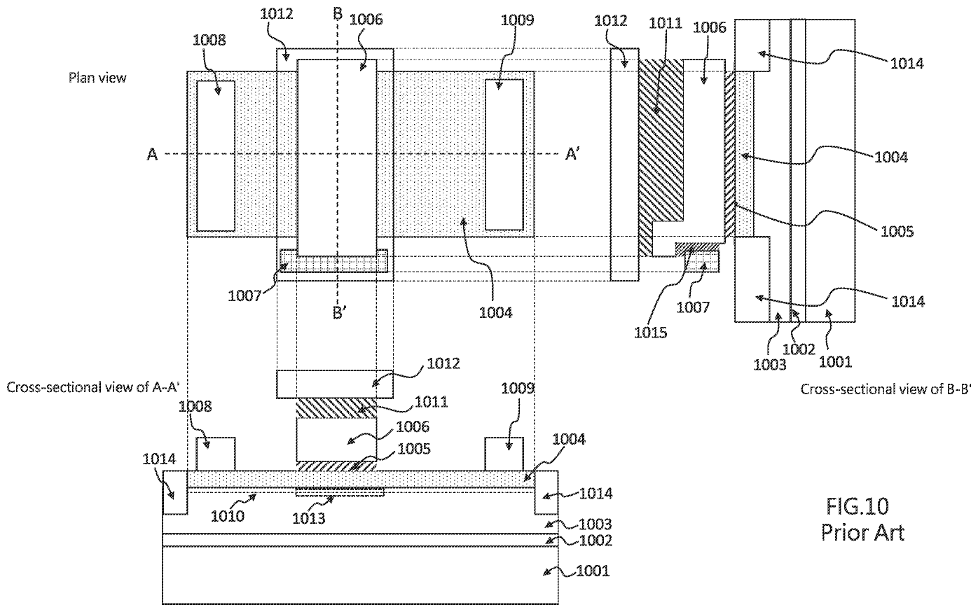

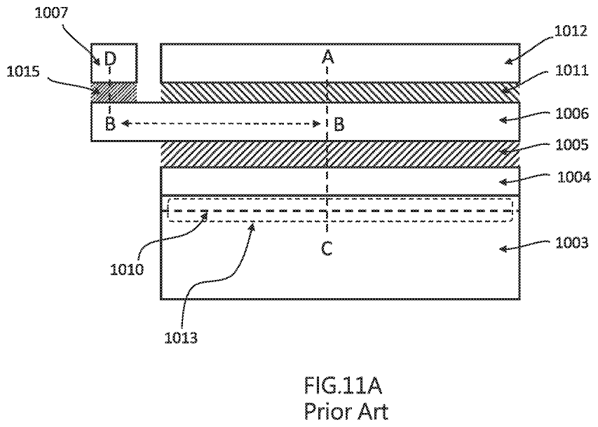

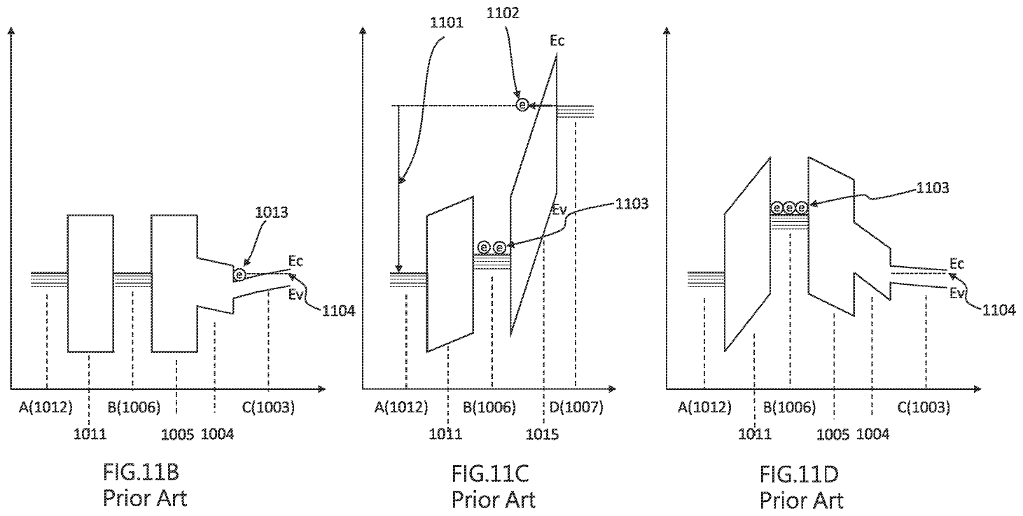

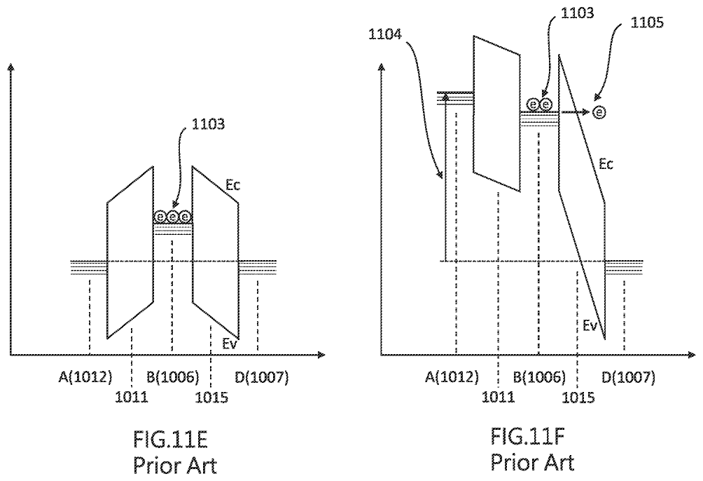

FIG. 9 is a view showing the structure of the field-effect transistor device according to another embodiment of the third invention of the present application. In this embodiment, multiple charge-accumulation gate electrodes 906 are formed on the first insulating film 905 above the second nitride semiconductor layer 104, and a gate electrode 912 is formed on the second insulating film 911 above the charge-accumulation gate electrode 906. The difference of this embodiment from the embodiment shown in FIG. 8 is that the multiple charge-accumulation gate electrodes 906 are arranged along the direction of the current flowing between the source electrode 908 and the drain electrode 109. The first capacitor is formed by the charge-accumulation gate electrodes 906 extending over the source electrodes 908. The embodiment shown in FIG. 8 was similar to the embodiment of the second invention of the present application shown in FIG. 4, whereas this embodiment is similar to the embodiment of the second invention of the present application shown in FIG. 6. Other parts are the same as in the embodiment shown in FIG. 8. Thus, the explanation regarding the embodiment shown in FIG. 8 applies almost similarly to other details. In this embodiment, unlike the embodiment shown in FIG. 8, the charge-accumulation gate electrodes 906 divided into multiple strips do not completely block the direction connecting the source electrode 908 and the drain electrode 109. Yet, even in this case, since carrier depletion in the conduction carrier 913 of the gate electrode portion due to the capacitive coupling with the gate electrode 912 also occurs in the lateral direction, the carriers can be eliminated in areas including the portion between the electrodes of the charge-accumulation gate electrodes 906, realizing an off-state. However, when the accumulated negative charge flows out of one of the multiple charge-accumulation gate electrodes 906, the current cannot be blocked in that portion, causing a leakage current during the off-state. Nevertheless, the rest of the device remains in the off-state, minimizing the effect on the entire device even when the FET is used as a switch.

In the above description, the cases of accumulating a negative charge on the charge-accumulation gate electrode are described as embodiments. This changes the threshold voltage in the positive direction in an FET with a conduction channel comprising n-type conduction carriers (conduction electrons) to obtain a normally-off characteristic. The invention of the present application, though, can also be applied to the case where a positive charge is accumulated in a charge-accumulation layer. In this case, interchanging the positions of the layers of the first semiconductor layer and the third insulating film in the multilayer film including the first semiconductor layer and the third insulating film can suppress the outflow of the accumulated positive charge when a voltage is applied to the first capacitor in the opposite direction to that during the positive charge accumulation. For example, when applied to an FET with a conduction channel including p-type conduction carriers (conduction holes), normally-off characteristics can be obtained.

In the above, applications of the present invention to nitride semiconductor FETs are described. Nitride semiconductor FETs, especially nitride semiconductor HEMTs, generally have very high negative threshold voltages as well, thus the present invention regarding a way of making FETs normally-off is especially effective. However, the invention is not limited to nitride semiconductor FETs, and can be applied to FETs using other semiconductor materials. For example, as well as nitride semiconductors, silicon carbide (SiC) is used as a material for FETs for power switches, and the invention of the present application is similarly applicable to FETs made using SiC. In addition, although the above invention describes a so-called horizontal FET in which the source and drain electrodes are formed on the same plane, it is similarly applicable to a vertical FET in which the current between the source and drain electrodes flows through the so-called drift layer in the vertical direction.

The field-effect transistor device according to the first through third inventions of the present application can be widely applied in addition to the power switches mainly described herein, for example, to transistors for high-frequency devices such as power amplifiers for wireless communications.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A field-effect transistor device comprising:
a semiconductor;
a conduction channel provided in or on a surface of the semiconductor;
a first insulating film provided in proximity to the conduction channel;
a charge-accumulation gate electrode provided at least in part above a side of the first insulating film opposite to the conduction channel;
a second insulating film provided above a side of the charge-accumulation gate electrode opposite to the first insulating film;
a gate electrode provided at least in part above a side of the second insulating film opposite to the charge-accumulation gate electrode;
a source electrode and a drain electrode provided on the semiconductor with the charge-accumulation gate electrode in between and electrically connected to the conduction channel;
a charge-injection electrode forming a first capacitor by capacitive coupling with the charge-accumulation gate electrode; and
a stacked film comprising a third insulating film and a first semiconductor layer provided between the charge-injection electrode and the charge-accumulation gate electrode,
wherein a charge is accumulated on the charge-accumulation gate electrode by a first current flowing through the first capacitor, and at least part of the first current flows through the stacked film.

2. The field-effect transistor device according to claim 1, wherein the semiconductor is a nitride semiconductor.

3. The field-effect transistor device according to claim 1, wherein the stacked film is provided in such a way that the third insulating film at least in part faces the charge-accumulation gate electrode and the first semiconductor layer at least in part faces the charge-injection electrode, and the first semiconductor layer includes n-type impurities.

4. The field-effect transistor device according to claim 1, wherein the stacked film is provided in such a way that the third insulating film at least in part faces the charge-injection electrode and the first semiconductor layer at least in part faces the charge-accumulation gate electrode, and the first semiconductor layer includes p-type impurities.

5. A field-effect transistor device comprising:
a semiconductor;
a conduction channel provided in or on a surface of the semiconductor;
a first insulating film provided in proximity to the conduction channel;
a charge-accumulation gate electrode provided at least in part above a side of the first insulating film opposite to the conduction channel;
a second insulating film provided above a side of the charge-accumulation gate electrode opposite to the first insulating film;
a gate electrode provided at least in part above a side of the second insulating film opposite to the charge-accumulation gate electrode; and
a source electrode and a drain electrode provided on the semiconductor with the charge-accumulation gate electrode in between and electrically connected to the conduction channel,
wherein the source electrode or the drain electrode forms a first capacitor by capacitive coupling with the charge-accumulation gate electrode, and a charge is accumulated on the charge-accumulation gate electrode by a first current flowing through the first capacitor.

6. The field-effect transistor device according to claim 5, wherein the semiconductor is a nitride semiconductor.

7. The field-effect transistor device according to claim 5, further comprising:
a stacked film comprising a third insulating film and a first semiconductor layer provided between the source electrode or the drain electrode and the charge-accumulation gate electrode forming the first capacitor,
wherein at least part of the first current flows through the stacked film.

8. The field-effect transistor device according to claim 7, wherein the stacked film is provided in such a way that the third insulating film at least in part faces the charge-accumulation gate electrode and the first semiconductor layer at least in part faces the source electrode or the drain electrode forming the first capacitor, and the first semiconductor layer includes n-type impurities.

9. The field-effect transistor device according to claim 7, wherein the stacked film is provided in such a way that the third insulating film at least in part faces the source electrode or the drain electrode forming the first capacitor and the first semiconductor layer at least in part faces the charge-accumulation gate electrode, and the first semiconductor layer includes p-type impurities.

10. A field-effect transistor device comprising:
a semiconductor;
a conduction channel provided in or on a surface of the semiconductor;
a first insulating film provided in proximity to the conduction channel;
a charge-accumulation gate electrode provided at least in part above a side of the first insulating film opposite to the conduction channel;
a second insulating film provided above a side of the charge-accumulation gate electrode opposite to the first insulating film;
a gate electrode provided at least in part above a side of the second insulating film opposite to the charge-accumulation gate electrode; and
a source electrode and a drain electrode provided on the semiconductor with the charge-accumulation gate electrode in between and electrically connected to the conduction channel,
wherein the charge-accumulation gate electrode comprises multiple separated electrodes.

11. The field-effect transistor device according to claim 10, wherein the semiconductor is a nitride semiconductor.

12. The field-effect transistor device according to claim 10, wherein all of the multiple electrodes of the charge-accumulation gate electrode are arranged to intersect a direction of the current in the conduction channel.

13. The field-effect transistor device according to claim 10, wherein all of the multiple electrodes of the charge-accumulation gate electrode are arranged along a direction of the current in the conduction channel.

14. The field-effect transistor device according to claim 10, further comprising:
a charge-injection electrode forming a first capacitor by capacitive coupling with the charge-accumulation gate electrode,
wherein a charge is accumulated on the charge-accumulation gate electrode by a first current flowing through the first capacitor.

15. The field-effect transistor device according to claim 14, further comprising:
a stacked film comprising a third insulating film and a first semiconductor layer provided between the charge-injection electrode and the charge-accumulation gate electrode,
wherein at least part of the first current flows through the stacked film.

16. The field-effect transistor device according to claim 15, wherein the stacked film is provided in such a way that the third insulating film at least in part faces the charge-accumulation gate electrode and the first semiconductor layer at least in part faces the charge-injection electrode, and the first semiconductor layer includes n-type impurities.

17. The field-effect transistor device according to claim 15, wherein the stacked film is provided in such a way that the third insulating film at least in part faces the charge-injection electrode and the first semiconductor layer at least in part faces the charge-accumulation gate electrode, and the first semiconductor layer includes p-type impurities.

18. The field-effect transistor device according to claim 10, wherein the source electrode or the drain electrode forms a first capacitor by capacitive coupling with the charge-accumulation gate electrode, and a charge is accumulated on the charge-accumulation gate electrode by a first current flowing through the first capacitor.

19. The field-effect transistor device according to claim 18, further comprising:
a stacked film comprising a third insulating film and a first semiconductor layer provided between the source electrode or the drain electrode and the charge-accumulation gate electrode forming the first capacitor,
wherein at least part of the first current flows through the stacked film.

20. The field-effect transistor device according to claim 19, wherein the stacked film is provided in such a way that the third insulating film at least in part faces the charge-accumulation gate electrode and the first semiconductor layer at least in part faces the source electrode or the drain electrode forming the first capacitor, and the first semiconductor layer includes n-type impurities.

21. The field-effect transistor device according to claim 19, wherein the stacked film is provided in such a way that the third insulating film at least in part faces the source electrode or the drain electrode forming the first capacitor and the first semiconductor layer at least in part faces the charge-accumulation gate electrode, and the first semiconductor layer includes p-type impurities.
